(19) United States
(12) Patent Application Publication
(10) Pub. No.: US 2024/0324250 A1
(43) Pub. Date: Sep. 26, 2024

(54) SEMICONDUCTOR MEMORY

(71) Applicant: Kioxia Corporation, Tokyo (JP)

(72) Inventors: Kosuke YANAGIDAIRA, Fujisawa Kanagawa (JP); Yoshikazu HOSOMURA, Kamakura Kanagawa (JP); Shouichi OZAKI, Komae Tokyo (JP)

(73) Assignee: Kioxia Corporation, Tokyo (JP)

(21) Appl. No.: 18/610,282

(22) Filed: Mar. 20, 2024

(30) Foreign Application Priority Data
Mar. 23, 2023 (JP) 2023-047220

(51) Int. Cl. H10B 80/00; G11C 16/04; G11C 16/10; G11C 16/16; G11C 16/26; G11C 16/34; H01L 23/00; H01L 23/522; H01L 25/065; H01L 25/18

(52) U.S. Cl. CPC H10B 80/00; G11C 16/0483; G11C 16/10; G11C 16/16; G11C 16/26; G11C 16/3445; G11C 16/3459; H01L 23/5225; H01L 24/08; H01L 25/0657; H01L 25/18; H01L 2224/08145; H01L 2924/1431; H01L 2924/14511

(57) ABSTRACT

According to one embodiment, a semiconductor memory includes a first chip including a substrate and a second chip bonded to the first chip. The second chip includes a first region including the memory cell array and the first shield line, and a second region including a second shield line. The first shield line is provided between the first chip and a memory cell array. The second shield line is provided in a same layer as the first shield line, and is not electrically coupled to the first shield line.

### CROSS-REFERENCE TO RELATED APPLICATION

This application is based upon and claims the benefit of priority from Japanese Patent Application No. 2023-047220, filed Mar. 23, 2023, the entire contents of which are incorporated herein by reference.

### FIELD

Embodiments described herein relate generally to a semiconductor memory.

### BACKGROUND

A NAND flash memory is known as a semiconductor memory.

### BRIEF DESCRIPTION OF THE DRAWINGS

FIG. 1 is a block diagram showing an example of a configuration of a memory system including a semiconductor memory according to a first embodiment.

FIG. 2 is a block diagram showing an example of a configuration of the semiconductor memory according to the first embodiment.

FIG. 3 is a circuit diagram showing an example of a circuit configuration of a memory cell array included in the semiconductor memory according to the first embodiment.

FIG. 4 is a circuit diagram showing an example of a circuit configuration of a row decoder module included in the semiconductor memory according to the first embodiment.

FIG. 5 is a block diagram showing an example of a configuration of a sense amplifier included in the semiconductor memory according to the first embodiment.

FIG. 6 is a circuit diagram showing an example of a circuit configuration of the sense amplifier included in the semiconductor memory according to the first embodiment.

FIG. 7 is a circuit diagram showing an example of a circuit configuration of a shield line driver included in the semiconductor memory according to the first embodiment.

FIG. 8 is a perspective view showing an outline of a bonded structure of the semiconductor memory according to the first embodiment.

FIG. 9 is a planar view showing an example of a planar layout of the semiconductor memory according to the first embodiment.

FIG. 10 is a planar view showing an example of a planar layout of an array chip included in the semiconductor memory according to the first embodiment.

FIG. 11 is a planar view showing an example of a planar layout of a shield line within the array chip included in the semiconductor memory according to the first embodiment.

FIG. 12 is a planar view showing an example of a planar layout of a circuit chip included in the semiconductor memory according to the first embodiment.

FIG. 13 is a planar view showing an example of a planar layout of peripheral circuits within the circuit chip included in the semiconductor memory according to the first embodiment.

FIG. 14 is a cross-sectional view showing an example of a cross-sectional structure of the semiconductor memory according to the first embodiment.

FIG. 15 is a cross-sectional view of a memory pillar and a vicinity of the memory pillar included in the semiconductor memory according to the first embodiment.

FIG. 16 is a cross-sectional view showing an example of a cross-sectional structure of the memory pillar included in the semiconductor memory according to the first embodiment.

FIG. 17 is a cross-sectional view showing an example of a cross-sectional structure of the semiconductor memory according to the first embodiment.

FIG. 18 is a cross-sectional view showing an example of the cross-sectional structure of the semiconductor memory according to the first embodiment.

FIG. 19 is a cross-sectional view showing an example of the cross-sectional structure of the semiconductor memory according to the first embodiment.

FIG. 20 is a cross-sectional view showing an example of the cross-sectional structure of the semiconductor memory according to the first embodiment.

FIG. 21 is a planar view showing an example of a planar layout of a shield line within an array chip included in a semiconductor memory according to a first modification of the first embodiment.

FIG. 22 is a planar view showing an example of a planar layout of an array chip included in a semiconductor memory according to a second modification of the first embodiment.

FIG. 23 is a conceptional diagram showing an example of a data storage method of a semiconductor memory according to a second embodiment.

FIG. 24 is a timing chart showing an outline of a write operation of the semiconductor memory according to the second embodiment.

FIG. 25 is a table showing an example of setting of a program loop in the write operation of the semiconductor memory according to the second embodiment.

FIG. 26 is a timing chart showing an example of voltages of respective interconnects during a program operation of the semiconductor memory according to the second embodiment.

FIG. 27 is a timing chart showing an example of voltages of respective interconnects during a program operation of a semiconductor memory according to a first modification of the second embodiment.

FIG. 28 is a timing chart showing an example of voltages of respective interconnects during the program operation of the semiconductor memory according to the first modification of the second embodiment.

FIG. 29 is a timing chart showing an example of voltages of respective interconnects during the program operation of the semiconductor memory according to the first modification of the second embodiment.

FIG. 30 is a timing chart showing an example of voltages of respective interconnects during the program operation of the semiconductor memory according to the first modification of the second embodiment.

FIG. 31 is a planar view showing an example of a planar layout of a shield line within an array chip included in a semiconductor memory according to a second modification of the second embodiment.

FIG. 32 is a cross-sectional view showing an example of a cross-sectional structure of the semiconductor memory according to the second modification of the second embodiment.

FIG. 33 is a timing chart showing an example of voltages of respective interconnects during a program operation of the semiconductor memory according to the second modification of the second embodiment.

FIG. 34 is a timing chart showing an example of voltages of respective interconnects during a read operation of a semiconductor memory according to a third modification of the second embodiment.

FIG. 35 is a timing chart showing an example of voltages of respective interconnects during a read operation of a semiconductor memory according to a fourth modification of the second embodiment.

FIG. 36 is a timing chart showing an example of voltages of respective interconnects during an erase voltage application operation of a semiconductor memory according to a fifth modification of the second embodiment.

FIG. 37 is a planar view showing an example of a planar layout of a shield line within an array chip included in a semiconductor memory according to a third embodiment.

### DETAILED DESCRIPTION

In general, according to one embodiment, a semiconductor memory includes a first chip including a first bonding surface and a substrate, the first bonding surface intersecting a first direction, and a second chip including a second bonding surface, the second bonding surface intersecting the first direction and bonded to the first bonding surface of the first chip. The second chip includes a first region including a memory cell array and a first shield line, and a second region including a second shield line. The first shield line is provided between the second bonding surface and the memory cell array. The second shield line is provided in a same layer as the first shield line, and is not electrically coupled to the first shield line.

Hereinafter, embodiments will be described with reference the accompanying drawings. The dimensions and ratios in the drawings are not always the same as the actual ones. In the following description, constituent elements having substantially the same function and configuration will be assigned the same reference symbol. In the case where elements having similar configurations are distinguished from each other in particular, their identical reference symbols may be assigned different letters or numbers.

### 1. First Embodiment

### 1.1 Configuration

### 1.1.1 Configuration of Memory System

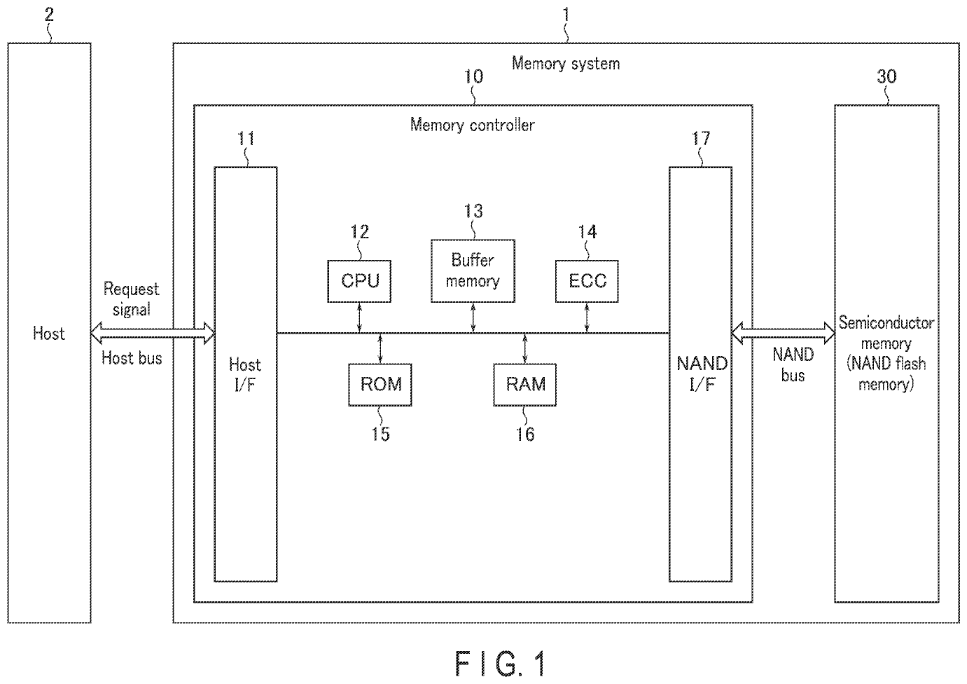

A configuration of a memory system including a semiconductor memory according to a first embodiment will be described with reference to FIG. 1. FIG. 1 is a block diagram showing an example of a configuration of a memory system including the semiconductor memory according to the first embodiment.

A memory system 1 is a device configured to store data. Examples of the memory system 1 include a solid state drive (SSD), a universal flash storage (UFS) device, a universal serial bus (USB) memory, a multi-media card (MMC), and an SD™ card. The memory system 1 can be coupled to a host 2 via a host bus. The memory system 1 performs processing based on a request signal received from the host 2 or a voluntary processing request. The request signal corresponds to request signals for various operations. The various operations are, for example, a write operation, a read operation, and an erase operation.

The host 2 is a device configured to control the memory system 1. Examples of the host 2 include a personal computer, a server system, a mobile device, a vehicle-mounted device, and a digital camera.

Next, the internal configuration of the memory system 1 will be described. As shown in FIG. 1, the memory system 1 includes a memory controller 10 and a semiconductor memory 30. The semiconductor memory 30 is, for example, a nonvolatile memory such as a NAND flash memory. Hereinafter, the semiconductor memory 30 will be referred to as a “NAND flash memory 30”.

The memory controller 10 is a device configured to control the NAND flash memory 30. The memory controller 10 is, for example, a system-on-a-chip (SoC). The memory controller 10 is coupled to the host 2 via a host bus. The memory controller 10 receives a request signal from the host 2 via the host bus. The memory controller 10 transmits information to the host 2 via the host bus. The type of host bus depends on an application applied in the memory system 1. In the case where the memory system 1 is an SSD, for example, an interface under serial attached SCSI (SAS), serial ATA (SATA), or peripheral component interconnect express (PCIe™) standard is used for the host bus. In the case where the memory system 1 is a UFS device, an interface under M-PHY standard is used for the host bus. In the case where the memory system 1 is a USB memory, an interface under USB standard is used for the host bus. In the case where the memory system 1 is an MMC, an interface under the embedded multi media card (eMMC) standard is used for the host bus. In the case where the memory system 1 is an SD™ card, an interface under SD™ standard is used for the host bus.

The memory controller 10 controls the NAND flash memory 30 via a NAND bus based on a request signal received from the host 2 or a voluntary processing request. The memory controller 10 transmits and receives data to and from, for example, the NAND flash memory 30, and transmits a command and an address thereto. The NAND bus performs signal transmission/reception in compliance with a NAND interface.

The NAND flash memory 30 is a device configured to store data. The NAND flash memory 30 includes a plurality of memory cell transistors. Each of the memory cell transistors stores data in a nonvolatile manner. The NAND flash memory 30 performs a write operation, a read operation, and an erase operation based on a command and an address received from the memory controller 10. In the write operation, the NAND flash memory 30 causes the plurality of memory cell transistors to store in a nonvolatile manner data received from the memory controller 10. In the read operation, the NAND flash memory 30 outputs data read from the plurality of memory cell transistors to the memory controller 10.

Next, the internal configuration of the memory controller 10 will be described. The memory controller 10 includes a host interface (I/F) circuit 11, a processor (Central Processing Unit: CPU) 12, a buffer memory 13, an error checking and correcting (ECC) circuit 14, a read-only memory (ROM) 15, a random access memory (RAM) 16, and a NAND interface (I/F) circuit 17.

The host interface circuit 11 is a circuit configured to manage communications between the memory controller 10 and the host 2. The host interface circuit 11 is coupled to the host 2 via the host bus.

The processor 12 is a control circuit of the memory controller 10. The processor 12 controls the overall operation of the memory controller 10 by executing a program (firmware) stored in the ROM 15. For example, upon receipt of a write request from host 2, the processor 12 controls a write operation based on the received write request. Similar processing is performed during the read operation and the erase operation.

The buffer memory 13 is a memory configured to temporarily store data. The buffer memory 13 is, for example, a static random access memory (SRAM). The buffer memory 13 temporarily stores write data, read data, etc. The write data is data that is written into the NAND flash memory 30. The read data is data that is read from the NAND flash memory 30.

The ECC circuit 14 is a circuit configured to execute error correction processing on data. Specifically, the ECC circuit 14 generates an error correction code based on write data during the data write operation. During the data read operation, the ECC circuit 14 detects an error by generating a syndrome based on an error correction code in a predetermined unit and corrects the detected error.

The ROM 15 is a nonvolatile memory. The ROM 15 is, for example, an electrically erasable programmable read-only memory (EEPROM™). The ROM 15 stores programs such as firmware, etc.

The RAM 16 is a volatile memory. The RAM 16 is, for example, an SRAM. The RAM 16 is used as a work area of the processor 12. The RAM 16 stores firmware for managing the NAND flash memory 30, and various types of management information.

The NAND interface circuit 17 is a circuit configured to manage communications between the memory controller 10 and the NAND flash memory 30. The NAND interface circuit 17 is coupled to the NAND flash memory 30 via a NAND bus. For example, the NAND interface circuit 17 controls the transfer of data, commands, addresses, etc., between the memory controller 10 and the NAND flash memory 30.

### 1.1.2 Configuration of NAND Flash Memory

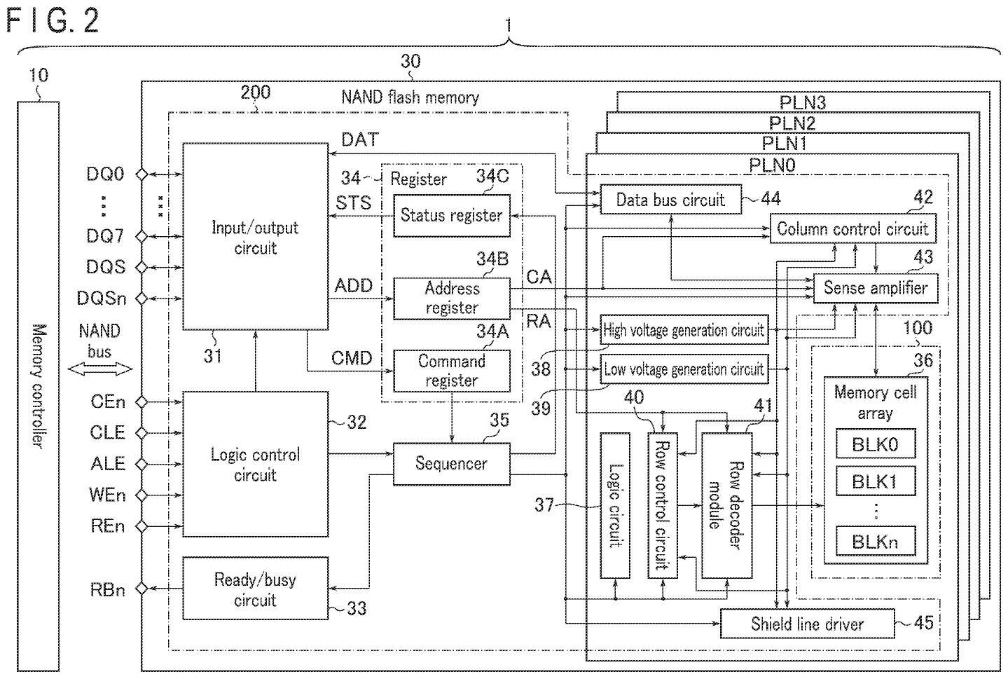

A configuration of the NAND flash memory 30 will be described with reference to FIG. 2. FIG. 2 is a block diagram showing an example of a configuration of the NAND flash memory 30.

As shown in FIG. 2, the NAND flash memory 30 includes an input/output circuit 31, a logic control circuit 32, a ready/busy circuit 33, a register 34, a sequencer 35, and a plurality of planes PLN.

The input/output circuit 31 is a circuit configured to transmit and receive signals and information to and from the memory controller 10. The input/output circuit 31 transmits and receives an input/output signal DQ (for example, 8-bit signals DQ0 to DQ7), a data strobe signal DQS, and a data strobe signal DQSn (an inversion signal of the signal DQS) to and from the memory controller 10. The signal DQ is an entity of data transmitted and received between the NAND flash memory 30 and the memory controller 10. The signal DQ includes, for example, a command CMD, an address ADD, status information STS, and data DAT. The signals DQS and DQSn are signals for controlling a timing of transmitting and receiving the signal DQ. For example, when data is written, the signals DQS and DQSn along with the data DQ including the write data are transmitted from the memory controller 10 to the NAND flash memory 30. The NAND flash memory 30 receives the signal DQ including the write data in synchronization with the signals DQS and DQSn. When data is read, the signals DQS and DQSn along with the signal DQ including the read data are transmitted from the NAND flash memory 30 to the memory controller 10. The memory controller 10 receives the signal DQ including the read data in synchronization with the signals DQS and DQSn. The input/output circuit 31 may receive the signals DQS and DQSn from the memory controller 10 via the logic control circuit 32.

The input/output circuit 31 transmits the command CMD in the signal DQ to a command register 34A. The input/output circuit 31 transmits the address ADD in the signal DQ to an address register 34B. The input/output circuit 31 receives the status information STS from a status register 34C. The input/output circuit 31 transmits and receives the data DAT in the signal DQ to and from a data bus circuit 44 in each plane PLN.

The logic control circuit 32 is a circuit configured to control the input/output circuit 31 and the sequencer 35 based on a control signal. The logic control circuit 32 receives a chip enable signal CEn, a command latch enable signal CLE, an address latch enable signal ALE, a write enable signal WEn, and a read enable signal REn from the memory controller 10. The signal CEn is a signal for enabling the NAND flash memory 30. The signal CLE is a signal indicating that the signal DQ received by the NAND flash memory 30 is the command CMD. The signal ALE is a signal indicating that the signal DQ received by the NAND flash memory 30 is the address ADD. The signal WEn is a signal instructing the NAND flash memory 30 to input the signal DQ. The signal REn is a signal instructing the NAND flash memory 30 to output the signal DQ. The NAND flash memory 30 generates the signals DQS and DQSn based on the signal REn. The NAND flash memory 30 outputs the signal DQ to the memory controller 10 based on the generated signals DQS and DQSn. The logic control circuit 32 controls the input/output circuit 31 and the sequencer 35 based on the received signal.

The ready/busy circuit 33 is a circuit configured to inform the memory controller 10 of an operation status of the sequencer 35. The ready/busy circuit 33 transmits the ready/busy signal RBn to the memory controller 10 based on an operation status of the sequencer 35. The signal RBn is a signal indicative of whether the NAND flash memory 30 is in a ready state or a busy state. The signal RBn is set to a “low” level, for example, when the NAND flash memory 30 is in a busy state. The ready state is a state in which the NAND flash memory 30 can receive a command from the memory controller 10. The busy state is a state in which the NAND flash memory 30 cannot receive a command from the memory controller 10.

The register 34 is a circuit configured to temporarily store information. The register 34 includes the command register 34A, the address register 34B, and the status register 34C.

The command register 34A is a circuit configured to store the command CMD. The command CMD includes, for example, an order for the sequencer 35 to execute the read operation, the write operation, and the erase operation.

The address register 34B is a circuit configured to store the address ADD. The address ADD includes, for example a row address RA (including a block address and a page address) and a column address CA. The block address, the page address, and the column address CA are respectively used for selection of a block BLK, a word line, and a bit line, for example. For example, the address register 34B transfers the row address RA to a row control circuit 40 and a row decoder module 41 in each plane PLN. The address register 34B transfers the column address CA to a column control circuit 42 and a sense amplifier 43 in each plane PLN.

The status register 34C is a circuit configured to temporarily store the status information STS during the read operation, the write operation, and the erase operation, for example. The status information STS is used to notify the memory controller 10 of whether or not the operation has been completed successfully.

The sequencer 35 is a circuit configured to control an operation of another circuit in accordance with a predetermined program. The sequencer 35 controls the operation of the entire NAND flash memory 30. For example, the sequencer 35 controls, based on the command CMD stored in the command register 34A, the ready/busy circuit 33, and a logic circuit 37, the high voltage generation circuit 38, the low voltage generation circuit 39, the row control circuit 40, the row decoder module 41, the column control circuit 42, the sense amplifier 43, the data bus circuit 44, and a shield line driver 45 in each plane PLN. For example, the sequencer 35 executes the read operation, the write operation, and the erase operation.

Each plane PLN is, for example, a unit (memory area) for execution of the write operation and read operation of data. In FIG. 2, the NAND flash memory 30 includes four planes PLN0, PLN1, PLN2, and PLN3. The number of planes PLN included in the NAND flash memory 30 is not limited to four. The plane PLN0 to PLN3 are independently operable. Furthermore, the planes PLN0 to PLN3 are also simultaneously operable. In other words, the NAND flash memory 30 has a plurality of memory areas that are independently controllable. Hereinafter, in the case of not specifying one of the planes PLN0 to PLN3, they will be referred to as a “plane PLN” or “planes PLN”.

Next, the internal configuration of the plane PLN will be described. The following will describe a case in which the planes PLN0 to PLN3 have the same configurations. Meanwhile, the planes PLN may respectively have different configurations. The plane PLN includes a memory cell array 36, the logic circuit 37, the high voltage generation circuit 38, the low voltage generation circuit 39, the row control circuit 40, the row decoder module 41, the column control circuit 42, the sense amplifier 43, the data bus circuit 44, and the shield line driver 45.

The memory cell array 36 includes a plurality of blocks BLK0 to BLKn (where n is an integer greater than or equal to 1). Hereinafter, in the case where the blocks BLK0 to BLKn are not distinguished from each other, they will be simply referred to as a “block BLK” or “blocks BLK”. The block BLK is, for example, a set of memory cell transistors, the data of which is erased in batches. For example, the block BLK is used as a unit of the data erase operation. The memory cell array 36 is provided with a plurality of bit lines and a plurality of word lines. The memory cell transistor is associated with, for example, a single bit line and a single word line. Furthermore, the memory cell array 36 is provided with a shield line. The shield line is, for example, an interconnect that cancels noise generated in another interconnect. The memory cell array 36 will be described later in detail.

The logic circuit 37 is a circuit configured to perform various logic arithmetic operations relating to control of the memory cell array 36. The logic circuit 37 performs, for example, an arithmetic operation relating to operations of the row control circuit 40 and the column control circuit 42.

The high voltage generation circuit 38 is a circuit that generates a comparatively high voltage for use in various operations. The high voltage generation circuit 38 supplies a generated voltage to, for example, the row control circuit 40, the row decoder module 41, the column control circuit 42, the sense amplifier 43, and the shield line driver 45.

The low voltage generation circuit 39 is a circuit that generates a comparatively low voltage for use in various operations. The low voltage generation circuit 39 supplies a generated voltage to, for example, the row control circuit 40, the row decoder module 41, the column control circuit 42, the sense amplifier 43, and the shield line driver 45.

The row control circuit 40 is a circuit that controls the row decoder module 41. The row control circuit 40 controls, for example, the row decoder module 41 by transmitting a control signal thereto.

The row decoder module 41 is a circuit configured to select, based on the row address RA, one of the blocks BLK within the memory cell array 36. The row decoder module 41 transfers a voltage applied to a signal line corresponding to a selected word line, to the selected word line within the selected block BLK.

The column control circuit 42 is a circuit configured to control the sense amplifier 43. The column control circuit 42 controls, for example, the sense amplifier 43 by transmitting a control signal thereto.

The sense amplifier 43 is a circuit configured to determine data stored in the memory cell transistor. In the read operation, the sense amplifier 43 determines data stored in the memory cell transistor based on a voltage of the bit line. The sense amplifier 43 transfers a result of the determination as read data DAT to the data bus circuit 44. In the write operation, the sense amplifier 43 applies to the bit line a voltage based on write data DAT received from the input/output circuit 31 via the data bus circuit 44.

The data bus circuit 44 is a circuit configured to perform transfer of data between the input/output circuit 31 and the sense amplifier 43.

The shield line driver 45 is a circuit configured to apply a voltage to the shield line. The shield line driver 45 applies a voltage according to various operations to the shield line.

Furthermore, as shown in FIG. 2, the NAND flash memory 30 includes an array chip 100 and a circuit chip 200. In the present embodiment, the NAND flash memory 30 has a structure (hereinafter referred to as a “bonded structure”) in which the array chip 100 and the circuit chip 200 are bonded together.

The array chip 100 is a chip provided with the memory cell arrays 36 of the planes PLN0 to PLN3. The circuit chip 200 is a chip provided with the input/output circuit 31, the logic control circuit 32, the ready/busy circuit 33, the register 34, the sequencer 35, and the logic circuits 37, the high voltage generation circuits 38, the low voltage generation circuits 39, the row control circuits 40, the row decoder modules 41, the column control circuits 42, the sense amplifiers 43, the data bus circuits 44, and the shield line drivers 45 which are provided in the planes PLN0 to PLN3. Meanwhile, a plurality of array chips 100 may be provided. In such a case, the plurality of array chips 100 may be bonded to the circuit chip 200 in such a manner that the array chips 100 are stacked on the circuit chip 200.

### 1.1.3 Circuit Configuration of Memory Cell Array

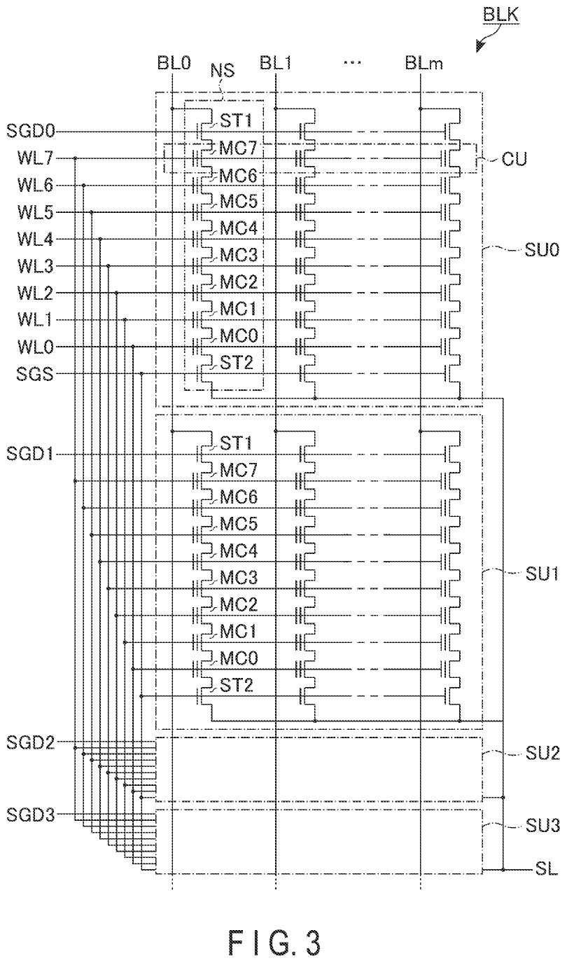

The circuit configuration of the memory cell array 36 will be described with reference to FIG. 3. FIG. 3 is a circuit diagram showing an example of the circuit configuration of the memory cell array 36. FIG. 3 shows a circuit configuration of the block BLK included in the memory cell array 36, as an example of the circuit configuration of the memory cell array 36. The other blocks BLK have similar configurations to the configuration shown in FIG. 3.

As shown in FIG. 3, the block BLK includes, for example, four string units SU0 to SU3. Hereinafter, in the case where the string units SU0 to SU3 are not distinguished from each other, they will be simply referred to as a “string unit SU” or “string units SU”. The string unit SU is a set of NAND strings NS which are selected in batch during the write operation or the read operation, for example. The string unit SU includes the plurality of NAND strings NS respectively associated with bit lines BL0 to BLm (where m is an integer equal to or greater than 1). Hereinafter, in the case where the bit lines BL0 to BLm are not distinguished from each other, they will be simply referred to as a “bit line BL” or “bit lines BL”. The NAND string NS is a set of memory cell transistors coupled in series. Each of the NAND strings NS includes, for example, memory cell transistors MC0 to MC7 and select transistors ST1 and ST2. Hereinafter, in the case where the memory cell transistors MC0 to MC7 are not distinguished from each other, they will be simply referred to as a “memory cell transistor MC” or “memory cell transistors MC”. Each of the memory cell transistors MC stores data in a nonvolatile manner. The memory cell transistor MC includes a control gate and a charge storage layer. The select transistors ST1 and ST2 are switching elements. Each of the select transistors ST1 and ST2 is used for selection of a string unit SU in various operations.

In the NAND string NS, the memory cell transistors MC0 to MC7 are coupled in series. A drain of the select transistor ST1 is coupled to the associated bit line BL. A source of the select transistor ST1 is coupled to one end of the memory cell transistors MC0 to MC7 coupled in series. A drain of the select transistor ST2 is coupled to the other end of the memory cell transistors MC0 to MC7 coupled in series. A source of the select transistor ST2 is coupled to a source line SL.

In the same block BLK, control gates of the memory cell transistors MC0 to MC7 are respectively coupled in common to word lines WL0 to WL7. Hereinafter, in the case where the word lines WL0 to WL7 are not distinguished from each other, they will be simply referred to as a “word line WL” or “word lines WL”. In each of the string units SU0 to SU3, gates of the select transistors ST1 are respectively coupled in common to select gate lines SGD0 to SGD3. Hereinafter, in the case where the select gate lines SGD0 to SGD3 are not distinguished from each other, they will be simply referred to as a “select gate line SGD” or “select gate lines SGD”. Gates of the select transistors ST2 included in the same block BLK are coupled in common to the select gate line SGS.

In the circuit configuration of the memory cell array 36 described in the above, a bit line BL is shared by the NAND strings NS assigned the same column address CAd among the plurality of string units SU, for example. The source line SL is shared by, for example, the plurality of blocks BLK.

A set of memory cell transistors MC coupled in common to a word line WL in a string unit SU is referred to as a cell unit CU, for example. The block BLK includes a plurality of cell units CU. Data stored in the cell unit CU including the plurality of memory cell transistors MC each adapted to store 1-bit data in accordance with a threshold voltage is equivalent to 1-page data. The cell unit CU may store 2-page data or more based on the number of bits of data that the memory cell transistor MC stores. The following will describe a case in which the memory cell transistor MC is a triple level cell (TLC) adapted to store 3-bit data.

Furthermore, the circuit configuration of the memory cell array 36 is not limited to the configuration described above. For example, the number of string units SU included in each block BLK may be any number. The number of memory cell transistors MC, the number of select transistors ST1, and the number of select transistors ST2 included in each NAND string NS may be any number. Hereinafter, the memory cell transistor MC will be also referred to as a “memory cell MC”.

### 1.1.4 Circuit Configuration of Row Decoder Module

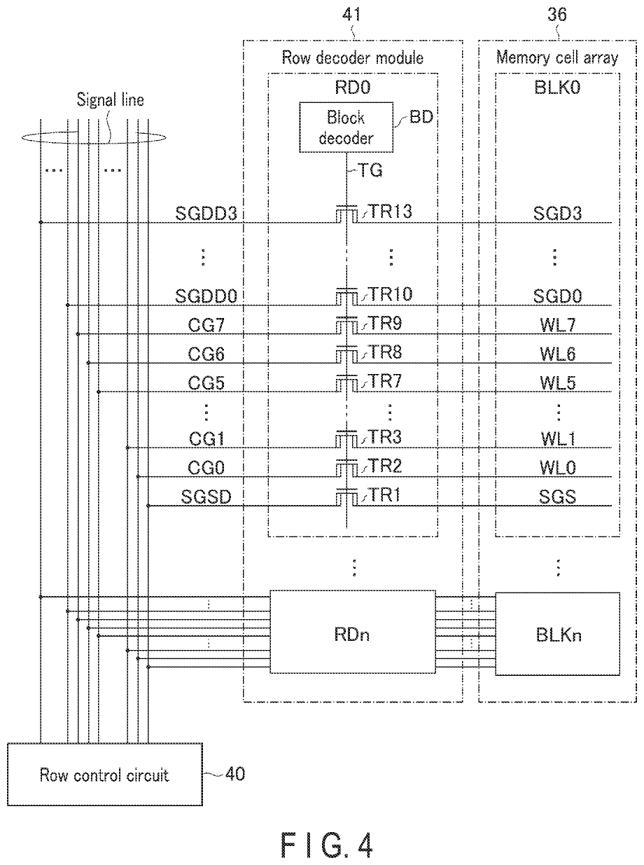

The circuit configuration of the row decoder module 41 will be described with reference to FIG. 4. FIG. 4 is a circuit diagram showing an example of the circuit configuration of the row decoder module 41.

As shown in FIG. 4, the row decoder module 41 includes, for example, row decoders RD0 to RDn. Hereinafter, in the case where the row decoders RD0 to RDn are not distinguished from each other, they will be simply referred to as a “row decoder RD” or “row decoders RD”. The row decoder RD is for use in selection of the block BLK. The row decoders RD0 to RDn are respectively associated with the blocks BLK0 to BLKn. Hereinafter, the circuit configuration of the row decoder RD will be described in detail, focusing on the row decoder RD0 corresponding to the block BLK0.

The row decoder RD includes, for example, a block decoder BD and high breakdown voltage n-channel MOS transistors TR1 to TR13.

The block decoder BD decodes a block address. The block decoder BD applies a predetermined voltage to a transfer gate line TG based on a result of the decoding. The transfer gate line TG is coupled in common to gates of the transistors TR1 to TR13. The transistors TR1 to TR13 are coupled between various signal lines extended from the row control circuit 40 and various interconnects of the associated block BLK.

Specifically, signal lines SGDD0 to SGDD3, signal lines CG0 to CG7, and a signal line SGSD are coupled to the row control circuit 40. The signal lines SGDD0 to SGDD3 respectively correspond to the select gate lines SGD0 to SGD3. Signal lines CG0 to CG7 respectively correspond to word lines WL0 to WL7. The signal line SGSD corresponds to the select gate line SGS.

One end of the transistor TR1 is coupled to the signal line SGSD, and the other end of the transistor TR1 is coupled to the select gate line SGS. One ends of the transistors TR2 to TR9 are respectively coupled to the signal lines CG0 to CG7, and the other ends of the transistors TR2 to TR9 are respectively coupled to the word lines WL0 to WL7. One ends of the transistors TR10 to TR13 are respectively coupled to the signal lines SGDD0 to SGDD3, and the other ends of the transistors TR10 to TR13 are respectively coupled to the select gate lines SGD0 to SGD3.

With the above configuration, the row decoder module 41 can select a block BLK for which various operations are performed.

Specifically, during various operations, the block decoder BD corresponding to the selected block BLK applies a voltage at an “H” level to the transfer gate line TG, and the block decoder BD corresponding to the non-selected block BLK applies a voltage at an “L” level to the transfer gate line TG.

For example, in the case where the block BLK0 is selected, the transistors TR1 to TR13 included in the row decoder RD0 are turned on, and the transistors TR1 to TR13 included in the other row decoders RD are turned off.

In such a case, a current path is formed between each of the various interconnects provided in the block BLK0 and a corresponding signal line, and a current path between each of the various interconnects provided in the other blocks BLK and a corresponding signal line is cut off. As a result, voltages respectively applied to the signal lines by the row control circuit 40 are applied via the row decoder RD0 to the various interconnects provided in the selected block BLK0. In the case where the other blocks BLK are selected, the row decoder module 41 can operate in a similar manner.

### 1.1.5 Configuration of Sense Amplifier

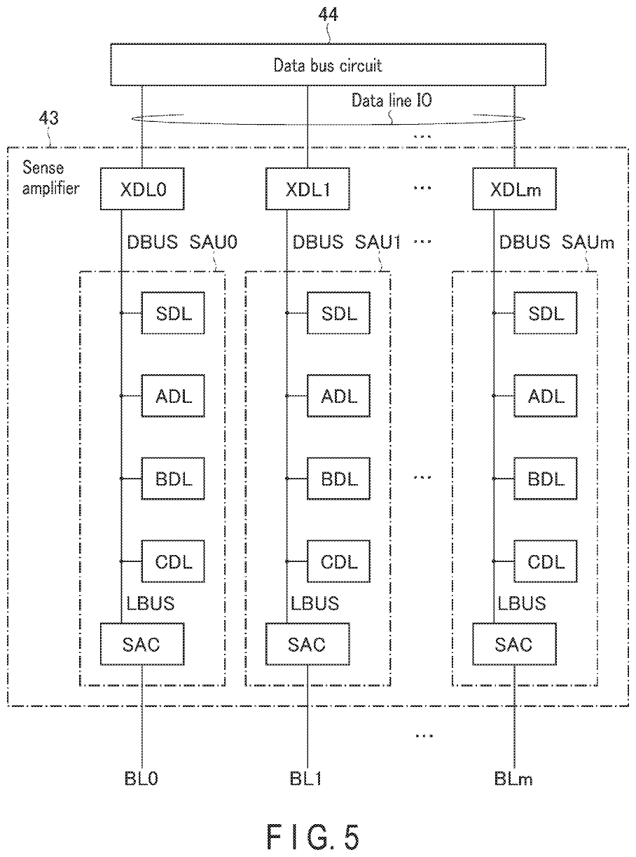

A configuration of the sense amplifier 43 will be described with reference to FIG. 5. FIG. 5 is a block diagram showing an example of a configuration of the sense amplifier 43.

As shown in FIG. 5, the sense amplifier 43 includes sense amplifier units SAU0 to SAUm and latch circuits XDL0 to XDLm. The sense amplifier units SAU0 to SAUm and the latch circuits XDL0 to XDLm are respectively associated with the bit lines BL0 to BLm. Hereinafter, in the case where the sense amplifier units SAU0 to SAUm are not distinguished from each other, they will be simply referred to as a “sense amplifier unit SAU” or “sense amplifier units SAU”. In the case where the latch circuits XDL0 to XDLm are not distinguished from each other, they will be simply referred to as a “latch circuit XDL” or “latch circuits XDL”.

The sense amplifier unit SAU is, for example, a sense amplifier unit of a current sensing type which senses a current flowing through the bit line BL.

The latch circuit XDL is a circuit configured to temporarily store read data and write data. The latch circuit XDL is used for input and output of data between the sense amplifier unit SAU and the input/output circuit 31. The latch circuit XDL is coupled to the corresponding sense amplifier unit SAU via a bus DBUS. A plurality of sense amplifier units SAU may be coupled to a single latch circuit XDL. Furthermore, the latch circuit XDL is coupled to the data bus circuit 44 via a corresponding data line IO.

Next, the internal configuration of the sense amplifier unit SAU will be described. The sense amplifier unit SAU includes, for example, a sense circuit SAC and latch circuits SDL, ADL, BDL, and CDL. The sense circuit SAC and the latch circuits SDL, ADL, BDL, and CDL are commonly coupled to the bus LBUS.

During the read operation, the sense circuit SAC senses data read to the corresponding bit line BL, and determines whether the read data is “0” or “1”. Furthermore, during the write operation, the sense circuit SAC applies a voltage to the bit line BL based on data stored in the latch circuit SDL.

The latch circuits SDL, ADL, BDL, and CDL are each a circuit configured to temporarily store read data and write data. For example, during the read operation, the sense circuit SAC may transfer data to any one of the latch circuits SDL, ADL, BDL, and CDL. Furthermore, during the write operation, the latch circuit XDL may transfer data to any one of the latch circuits SDL, ADL, BDL, and CDL.

The configuration of the sense amplifier unit SAU is not limited to the above configuration, and various modifications can be made. For example, the number of latch circuits included in the sense amplifier unit SAU may be designed based on the number of bits of data that a single memory cell MC stores.

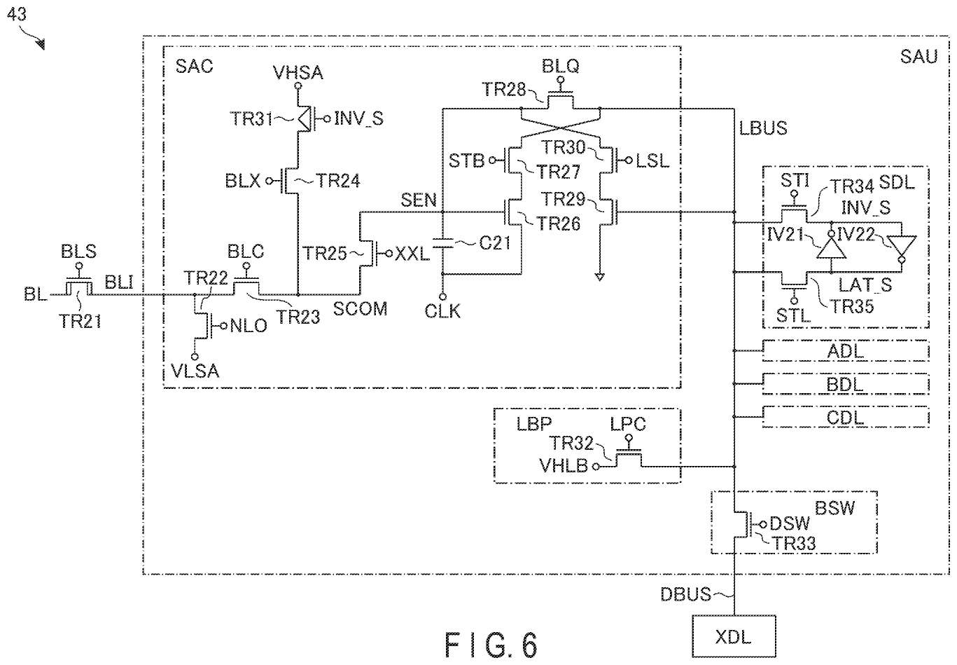

Next, the circuit configuration of the sense amplifier 43 will be described with reference to FIG. 6. FIG. 6 is a circuit diagram showing an example of the circuit configuration of the sense amplifier 43. In FIG. 6, one of the sense amplifier units SAU included in the sense amplifier 43 is extracted and shown. The other sense amplifier units also have similar configurations to that shown in FIG. 6.

As shown in FIG. 6, the sense amplifier 43 includes, in addition to the configuration shown in FIG. 5, a high breakdown voltage n-channel MOS transistor TR21 corresponding to the sense amplifier unit SAU. In other words, the transistor TR21 is provided for each sense amplifier unit SAU in the sense amplifier 43.

One end of the transistor TR21 is coupled to an interconnect BLI. The other end of the transistor TR21 is coupled to the corresponding bit line BL. A control signal BLS is input to a gate of the transistor TR21. The control signal BLS is generated by, for example, the sequencer 35. The transistor TR21 is used to prevent supply of a high voltage to the sense amplifier unit SAU, for example.

As shown in FIG. 6, the sense amplifier unit SAU includes a sense circuit SAC, a pre-charge circuit LBP, a bus switch BSW, and four latch circuits SDL, ADL, BDL, and CDL.

First, the circuit configuration of the sense circuit SAC will be described. The sense circuit SAC includes n-channel MOS transistors TR22 to TR30, a p-channel MOS transistor TR31, and a capacitance element C21.

One end of the transistor TR22 is coupled to the interconnect BLI. A voltage VLSA is applied to the other end of the transistor TR22. The voltage VLSA is, for example, a ground voltage VSS. A control signal NLO is input to a gate of the transistor TR22. The control signal NLO is generated by, for example, the sequencer 35. The transistor TR22 is used in charging or discharging of the corresponding bit line BL, for example.

One end of the transistor TR23 is coupled to the interconnect BLI. The other end of the transistor TR23 is coupled to the node SCOM. A control signal BLC is input to a gate of the transistor TR23. The control signal BLC is generated by, for example, the sequencer 35. The transistor TR23 is used in clamping of the corresponding bit line BL to a voltage according to the signal BLC, for example.

One end of the transistor TR24 is coupled to the node SCOM. The other end of the transistor TR24 is coupled to one end of the transistor TR31. A control signal BLX is input to a gate of the transistor TR24. The control signal BLX is generated by, for example, the sequencer 35.

One end of the transistor TR25 is coupled to the node SCOM. The other end of the transistor TR25 is coupled to the node SEN. A control signal XXL is input to a gate of the transistor TR25. The control signal XXL is generated by, for example, the sequencer 35. The transistor TR25 is used in control of a period during which data in a memory cell MC is sensed. The node SEN functions as a sense node for sensing data in the memory cell MC which is a read target during a data read operation. More specifically, during the read operation, electric charge pre-charged into the node SEN (and the capacitance element C21) is transferred to the bit line BL in accordance with whether the memory cell MC, which is a read target, is in an on state or an off state. Data is read by sensing a voltage of the node SEN at this time.

A clock signal CLK is input to one end of the transistor TR26. The other end of the transistor TR26 is coupled to one end of the transistor TR27. A gate of the transistor TR26 is coupled to the node SEN.

The other end of the transistor TR27 is coupled to the bus LBUS. A control signal STB is input to a gate of the transistor TR27. The control signal STB is generated by, for example, the sequencer 35.

One end of the transistor TR28 is coupled to the node SEN. The other end of the transistor TR28 is coupled to the bus LBUS. A control signal BLQ is input to a gate of the transistor TR28. The control signal BLQ is generated by, for example, the sequencer 35.

One end of the transistor TR29 is grounded. The other end of the transistor TR29 is coupled to one end of the transistor TR30. A gate of the transistor TR29 is coupled to the bus LBUS.

The other end of the transistor TR30 is coupled to the node SEN. A control signal LSL is input to a gate of the transistor TR30. The control signal LSL is generated by, for example, the sequencer 35.

A voltage VHSA is applied to the other end of the transistor TR31. The voltage VHSA is, for example, a power supply voltage VCC. A gate of the transistor TR31 is coupled to a node INV_S to be described later.

One electrode of the capacitance element C21 is coupled to the node SEN. The clock signal CLK is input to the other electrode of the capacitance element C21.

Next, the circuit configuration of the pre-charge circuit LBP will be described. The pre-charge circuit LBP is a circuit configured to pre-charge the bus LBUS. The pre-charge circuit LBP includes an n-channel MOS transistor TR32.

One end of the transistor TR32 is coupled to the bus LBUS. A voltage VHLB is applied to the other end of the transistor TR32. The voltage VHLB is, for example, the power supply voltage VCC. A control signal LPC is input to a gate of the transistor TR32. The control signal LPC is generated by, for example, the sequencer 35. In the case of the transistor TR32 being in the on state, the voltage VHLB is applied to the bus LBUS. In this manner, the bus LBUS is charged.

Next, the circuit configuration of the bus switch BSW will be described. The bus switch BSW is a switch for coupling the bus LBUS and the bus DBUS. The bus switch BSW includes an n-channel MOS transistor TR33.

One end of the transistor TR33 is coupled to the bus LBUS. The other end of the transistor TR33 is coupled to the bus DBUS. A control signal DSW is input to a gate of the transistor TR33. The control signal DSW is generated by, for example, the sequencer 35.

Next, the circuit configurations of the latch circuits SDL, ADL, BDL, and CDL will be described. The latch circuit SDL includes n-channel MOS transistors TR34 and TR35, and inverter circuits IV21 and IV22.

One end of the transistor TR34 is coupled to the bus LBUS. The other end of transistor TR34 is coupled to the node INV_S. A control signal ST1 is input to a gate of the transistor TR34. The control signal ST1 is generated by, for example, the sequencer 35.

One end of the transistor TR35 is coupled to the bus LBUS. The other end of the transistor TR35 is coupled to a node LAT_S. A control signal STL is input to a gate of the transistor TR35. The control signal STL is generated by, for example, the sequencer 35.

An input terminal of the inverter circuit IV21 is coupled to the node LAT_S. An output terminal of the inverter circuit IV21 is coupled to the node INV_S.

An input terminal of the inverter circuit IV22 is coupled to the node INV_S. An output terminal of the inverter circuit IV22 is coupled to the node LAT_S.

The latch circuits ADL, BDL, and CDL have similar configurations to that of the latch circuit SDL.

As described above, in the sense amplifier unit SAU, the sense circuit SAC and the latch circuits SDL, ADL, BDL, and CDL are coupled to the bus LBUS such that data can be transmitted and received therebetween.

The latch circuit XDL has a similar configuration to that of the latch circuit SDL, too.

### 1.1.6 Circuit Configuration of Shield Line Driver

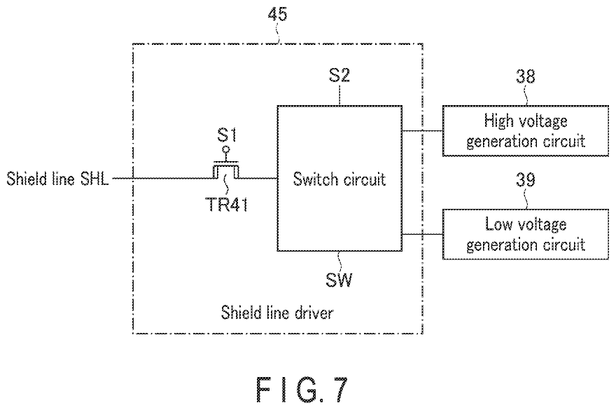

The circuit configuration of the shield line driver 45 will be described with reference to FIG. 7. FIG. 7 is a circuit diagram showing an example of the circuit configuration of the shield line driver 45.

As shown in FIG. 7, the shield line driver 45 includes a high breakdown voltage n-channel MOS transistor TR41 and a switch circuit SW. The switch circuit SW is a circuit configured to switch coupling between the transistor TR41 and the high voltage generation circuit 38, and coupling between the transistor TR41 and the low voltage generation circuit 39. One end of the transistor TR41 is coupled to the switch circuit SW. The other end of the transistor TR41 is coupled to a shield line SHL. A control signal S1 is input to a gate of the transistor TR41. The control signal S1 is generated by, for example, the sequencer 35. The switch circuit SW is coupled to the high voltage generation circuit 38 and the low voltage generation circuit 39. A control signal S2 is input to the switch circuit SW. The control signal S2 is generated by, for example, the sequencer 35. The switch circuit SW switches coupling based on the control signal S2. In the case of the transistor TR41 being in the on state, coupling of the switch circuit SW is switched based on the control signal S2, so that a voltage is applied to the shield line SHL from the high voltage generation circuit 38 or the low voltage generation circuit 39 coupled to one end of the transistor TR41. The shield line driver 45 may be provided with two or more transistors TR41.

### 1.1.7 Bonded Structure of NAND Flash Memory

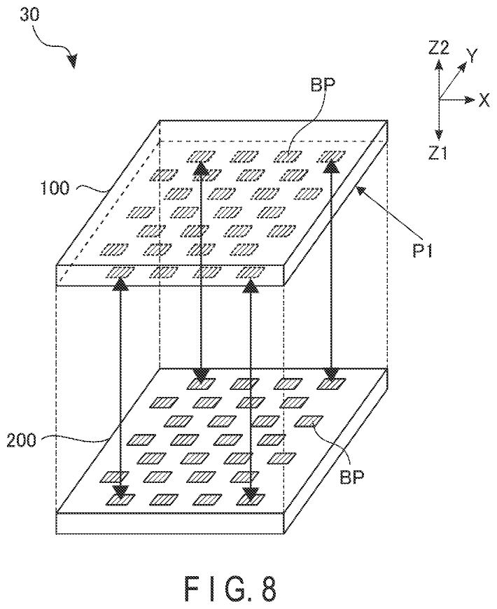

An outline of the bonded structure of the NAND flash memory 30 will be described with reference to FIG. 8. FIG. 8 is a perspective view showing an outline of the bonded structure of the NAND flash memory 30.

As shown in FIG. 8, the array chip 100 is bonded to the circuit chip 200 with a first surface P1 of the array chip 100 being bonded thereto, for example. Each of the array chip 100 and the circuit chip 200 includes a plurality of bonding pads BP provided on their surfaces facing each other. With the bonded structure, each bonding pad BP of the array chip 100 and each bonding pad BP of the circuit chip 200 are bonded to form a single bonding pad BP. In other words, each bonding pad BP is formed by bonding an electrode (conductor) configuring each bonding pad BP provided on the array chip 100 to an electrode (conductor) configuring each bonding pad BP provided on the circuit chip 200.

Hereinafter, the surface on which the array chip 100 and the circuit chip 200 are bonded together (hereinafter referred to as a “bonding surface”) will be referred to as an XY plane. The bonding surface is, for example, the first surface P1 of the array chip 100. Within the XY plane, two directions orthogonal to each other will be referred to as an “X direction” and a “Y direction”. Furthermore, a direction that is substantially perpendicular to the XY plane and extends from the array chip 100 to the circuit chip 200 will be referred to as a “Z1 direction”. A direction that is substantially perpendicular to the XY plane and extends from the circuit chip 200 to the array chip 100 will be referred to as a “Z2” direction. The Z1 direction and the 22 direction will each be referred to as a Z direction in the case where they are not distinguished from each other.

### 1.1.8 Layout of NAND Flash Memory

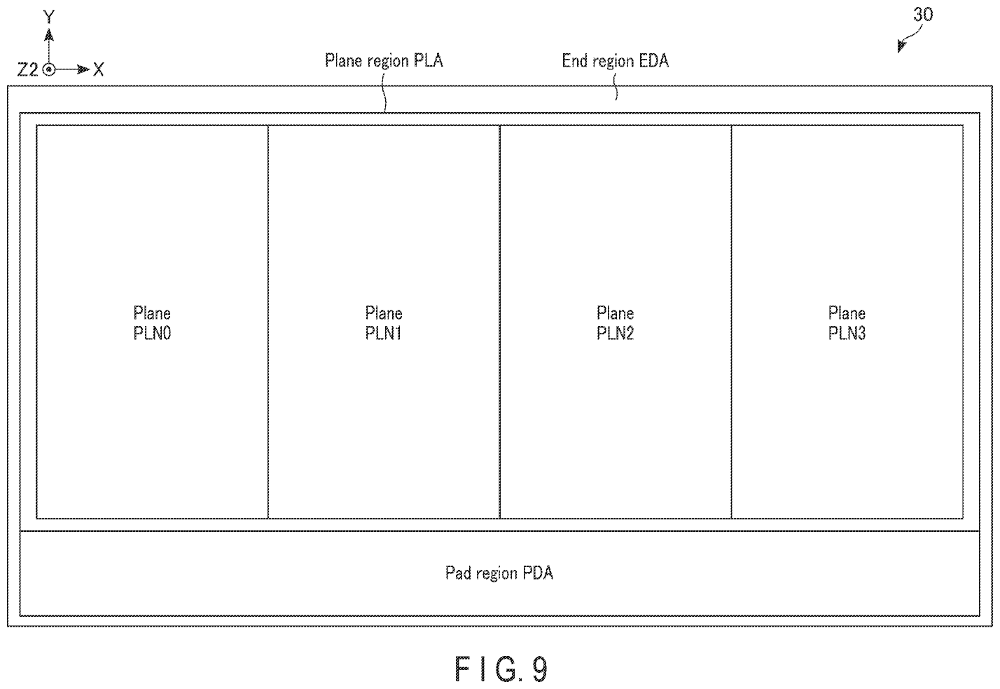

A planar layout of the NAND flash memory 30 will be described with reference to FIG. 9. FIG. 9 is a planar view showing an example of a planar layout of the NAND flash memory 30.

As shown in FIG. 9, the planar layout of the NAND flash memory 30 includes a plane region PLA, a pad region PDA, and an end region EDA.

The plane region PLA is a region in which the planes PLN0 to PLN3 are provided. In the plane region PLA, the planes PLN0 to PLN3 are arranged side by side in the X direction, for example.

The pad region PDA is a region in which a pad PD for use in coupling between an outside of the NAND flash memory 30 and the circuit chip 200 is provided. The pad region PDA and the plane region PLA are arranged side by side in the Y direction, for example.

The end region EDA is, for example, a square ring-shaped region provided so as to surround the plane region PLA and the pad region PDA. In other words, the pad region PDA and the end region EDA correspond to a region surrounding the plane region PLA. The end region EDA includes an end portion of the NAND flash memory 30.

### 1.1.9 Layout of Array Chip

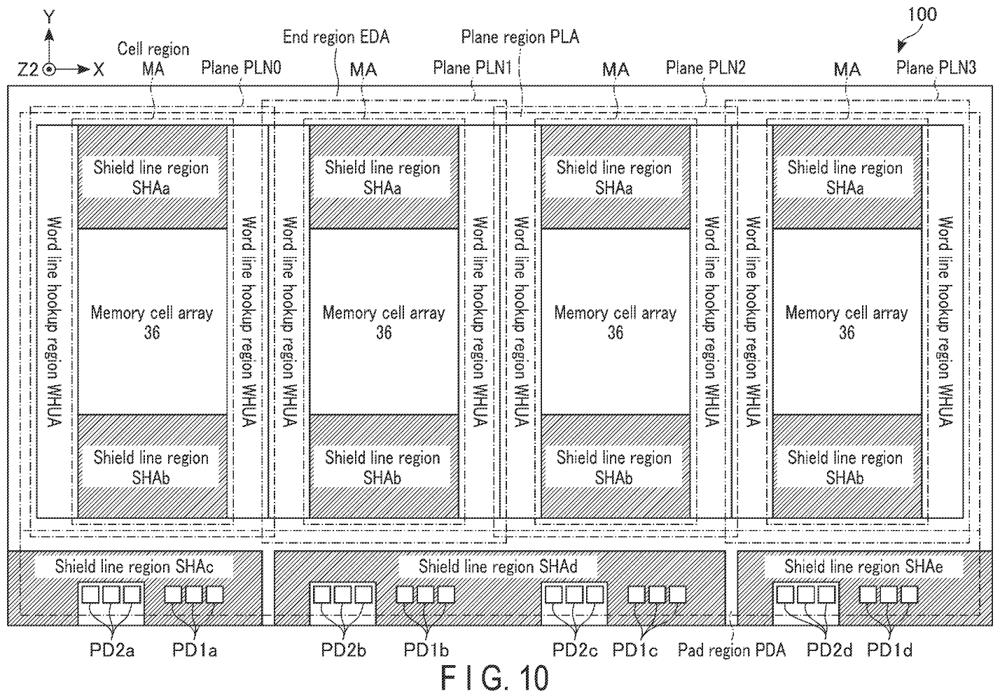

A planar layout of the array chip 100 will be described with reference to FIG. 10. FIG. 10 is a planar view showing an example of a planar layout of the array chip 100. Meanwhile, the plane region PLA, the planes PLN0 to PLN3, the pad region PDA, and the end region EDA shown in FIG. 10 respectively correspond to the plane region PLA, the planes PLN0 to PLN3, the pad region PDA, and the end region EDA shown in FIG. 9. That is, the array chip 100 includes the plane region PLA, the pad region PDA, and the end region EDA.

As shown in FIG. 10, the array chip 100 includes a cell region MA and two word line hookup regions WHUA within the plane PLN0. The cell region MA is a region in which the memory cell array 36 is provided. The word line hookup region WHUA is a region for use in coupling between the word line WL and the row decoder module 41. Two word line hookup regions WHUA are arranged side by side in the X direction, for example. The cell region MA is arranged between two word line hookup regions WHUA, for example.

The cell region MA includes the memory cell array 36 and two shield line regions SHAa and SHAb. In other words, the plane region PLA of the array chip 100 includes the memory cell array 36. The shield line regions SHAa and SHAb are each a region in which the shield line SHL is provided. The memory cell array 36 is arranged throughout the cell region MA, for example. The shield line regions SHAa and SHAb are respectively arranged on both ends in the Y direction of the cell region MA, for example. In other words, each of the shield line regions SHAa and SHAb overlaps the memory cell array 36 in the Z direction.

In the array chip 100, configurations in the plane PLN1 to PLN3 are similar to that of the plane PLN0.

The array chip 100 includes a plurality of pads PD1a to PD1d and a plurality of pads PD2a to PD2d within the pad region PDA. The pads PD1a to PD1d are each a power supply pad for supplying a voltage to the shield line SHL, for example. The power supply voltage VCC is externally supplied to the pads PD1a and PD1d, for example. The voltage VCCQ or VCCQL is externally supplied to the pads PD1b and PD1c, for example. The voltages VCCQ and VCCQL are each a voltage for use in the input/output circuit 31. The voltages VCC, VCCQ, and VCCQL have a magnitude relationship expressed as VCC>VCCQ>VCCQL. Hereinafter, in the case where the pads PD1a to PD1d are not distinguished from each other, they will be simply referred to as a “pad PD1” or “pads PD1”. The pads PD2a to PD2d are each a power supply voltage pad for supplying the voltage VCCQ or VCCQL to the input/output circuit 31, for example. For example, the voltage VCCQ or VCCQL is externally supplied to the pads PD2a to PD2d. Hereinafter, in the case where the pads PD2a to PD2d are not distinguished from each other, they will be simply referred to as a “pad PD2” or “pads PD2”.

The plurality of pads PD1a and the plurality of pads PD2a are a group of pads corresponding to the plane PLN0. The plurality of pads PD1a and the plurality of pads PD2a are arranged in, for example, a position facing the plane PLN0 in the Y direction. The plurality of pads PD1a and the plurality of pads PD2a are arranged side by side in the X direction, for example.

The plurality of pads PD1b and the plurality of pads PD2b are a group of pads corresponding to the plane PLN1. The plurality of pads PD1b and the plurality of pads PD2b are arranged in, for example, a position facing the plane PLN1 in the Y direction. The plurality of pads PD1b and the plurality of pads PD2b are arranged side by side in the X direction, for example.

The plurality of pads PD1c and the plurality of pads PD2c are a group of pads corresponding to the plane PLN2. The plurality of pads PD1c and the plurality of pads PD2c are arranged in, for example, a position facing the plane PLN2 in the Y direction. The plurality of pads PD1c and the plurality of pads PD2c are arranged side by side in the X direction, for example.

The plurality of pads PD1d and the plurality of pads PD2d are a group of pads corresponding to the plane PLN3. The plurality of pads PD1d and the plurality of pads PD2d are arranged in, for example, a position facing the plane PLN3 in the Y direction. The plurality of pads PD1d and the plurality of pads PD2d are arranged side by side in the X direction, for example.

In FIG. 10, both the number of the pads PD1 corresponding to each plane PLN and the number of the pads PD2 corresponding to each plane PLN are three. The number of the pads PD1 corresponding to each plane PLN and the number of the pads PD2 corresponding to each plane PLN are not limited to three.

The array chip 100 includes the shield line regions SHAc, SHAd, and SHAe within the pad region PDA and the end region EDA. The shield line regions SHAc, SHAd, and SHAe are each a region in which the shield line SHL is arranged. Hereinafter, a combination of the pad region PDA and the end region EDA will be also referred to as a “non-plane region”.

The shield line region SHAc is a shield line region corresponding to the plane PLN0. The shield line region SHAc is arranged in, for example, a position facing the plane PLN0 in the Y direction in such a manner as to extend from the pad region PDA to the end region EDA. The shield line region SHAc is arranged in such a manner as to bypass the plurality of pads PD2a, for example. In other words, a part of the lower end portion of the shield line region SHAc does not reach the lower end portion of the array chip 100. The left end portion of the shield line region SHAc reaches the left end portion of the array chip 100.

A shield line region SHAd is a shield line region corresponding to two planes PLN1 and PLN2. The shield line region SHAd is arranged in, for example, a position facing the planes PLN1 and PLN2 in the Y direction in such a manner as to extend from the pad region PDA to the end region EDA. The shield line region SHAd is arranged in such a manner as to bypass the plurality of pads PD2b and PD2c, for example. In other words, a part of the lower end portion of the shield line region SHAd does not reach the lower end portion of the array chip 100. The left end portion of the shield line region SHAd is apart in the X direction from the right end portion of the shield line region SHAc.

The shield line region SHAe is a shield line region corresponding to the plane PLN3. The shield line region SHAe is arranged in, for example, a position facing the planes PLN3 in the Y direction in such a manner as to extend from the pad region PDA to the end region EDA. The shield line region SHAe is arranged in such a manner as to bypass the plurality of pads PD2d, for example. In other words, a part of the lower end portion of the shield line region SHAe does not reach the lower end portion of the array chip 100. The left end portion of the shield line region SHAe is apart in the X direction from the right end portion of the shield line region SHAd. The right end portion of the shield line region SHAe reaches the right end portion of the array chip 100.

Each of the shield lines SHL provided in the shield line regions SHAc, SHAd, and SHAe covers a part of the lower end, a part of the left end, and a part of the right end of the non-plane region.

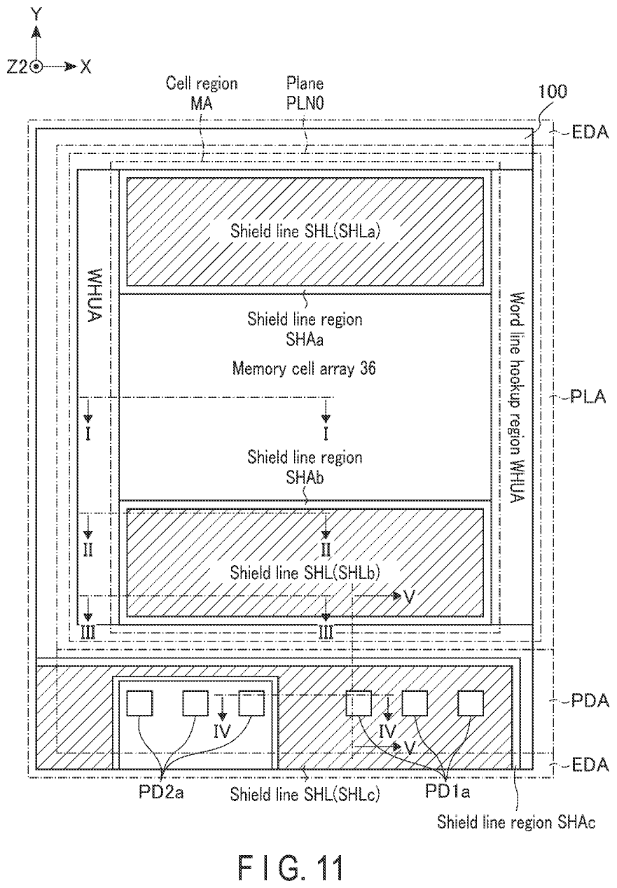

FIG. 11 is a planar view showing an example of a planar layout of the shield lines SHL within the array chip 100. FIG. 11 shows the plane PLN0, and the shield line region SHAc and pads PD1a and PD2a which correspond to the plane PLN0.

In the shield line regions SHAa, SHAb, and SHAc, the shield lines SHL are each formed into, for example, a plate shape extending on the XY plane. Hereinafter, the shield lines SHL provided in the shield line regions SHAa, SHAb, and SHAc will be also referred to as shield lines SHLa, SHLb, and SHLc, respectively. To facilitate understanding, FIG. 10 shows that the end portion of the shield line SHLa is positioned inside the end portion of the shield line region SHAa; however, the shield line SHLa is actually provided throughout the shield line region SHAa, for example. The same applies to the shield lines SHLb and SHLc. The shield line SHLa is spaced apart from the shield line SHLb in the Y direction. The shield line SHLb is spaced apart from the shield line SHLc in the Y direction. Furthermore, the shield line SHLc is provided in such a manner as to extend from the pad region PDA to the end region EDA. The shield line SHLc is provided in such a manner as to avoid overlap with the plurality of pads PD2a in the Z direction, for example.

As described above, the plane region PLA of the array chip 100 includes the shield lines SHLa and SHLb. The non-plane region of the array chip 100 includes the shield line SHLC.

### 1.1.10 Layout of Circuit Chip

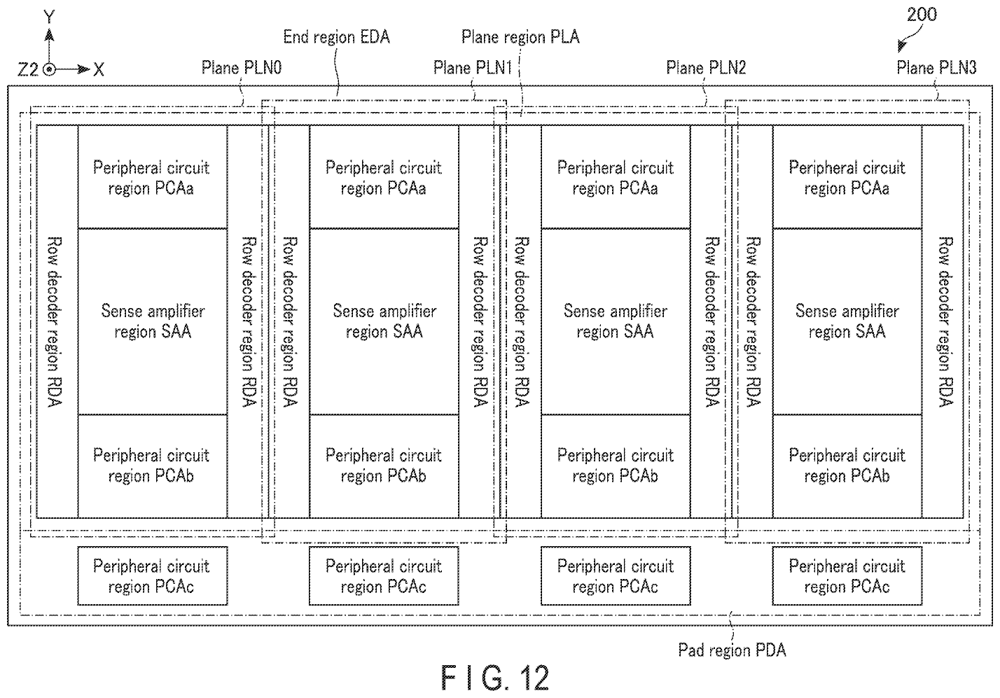

The planar layout of the circuit chip 200 will be described with reference to FIG. 12. FIG. 12 is a planar view showing an example of a planar layout of the circuit chip 200. Meanwhile, the plane region PLA, the planes PLN0 to PLN3, the pad region PDA, and the end region EDA shown in FIG. 12 respectively correspond to the plane region PLA, the planes PLN0 to PLN3, the pad region PDA, and the end region EDA shown in FIG. 9. That is, the circuit chip 200 includes the plane region PLA, the pad region PDA, and the end region EDA.

As shown in FIG. 12, the circuit chip 200 includes a sense amplifier region SAA, peripheral circuit regions PCAa and PCAb, and two row decoder regions RDA within the plane PLN0. The sense amplifier region SAA is a region in which the sense amplifier 43 is provided. The peripheral circuit regions PCAa and PCAb are each a region in which peripheral circuits such as the row control circuit 40 and the column control circuit 42, etc. are provided. The row decoder region RDA is a region in which the row decoder module 41 is provided. Two row decoder regions RDA are arranged side by side in the X direction, for example. The row decoder region RDA corresponds to the word line hookup region WHUA of the array chip 100. The sense amplifier region SAA and the peripheral circuit regions PCAa and PCAb are arranged between, for example, two row decoder regions RDA. The sense amplifier region SAA and the peripheral circuit regions PCAa and PCAb correspond to the cell region MA of the array chip 100. The peripheral circuit regions PCAa and PCAb are arranged side by side in the Y direction, for example. The sense amplifier region SAA is arranged between, for example, the peripheral circuit regions PCAa and PCAb. In other words, the sense amplifier 43 provided in the sense amplifier region SAA does not overlap the shield line SHL in the Z direction.

In the circuit chip 200, configurations in the planes PLN1 to PLN3 are similar to that of the plane PLN0.

The circuit chip 200 includes a plurality of peripheral circuit regions PDAc within the pad region PDA. The peripheral circuit region PDAc is a region in which the peripheral circuits, such as the input/output circuit 31, etc., are provided. The plurality of peripheral circuit regions PDAc are peripheral circuit regions corresponding to the planes PLN0 to PLN3, respectively. The peripheral circuit region PDAc is arranged in, for example, a position facing the corresponding plane PLN in the Y direction. The plurality of peripheral circuit regions PDAc are arranged side by side in the X direction, for example.

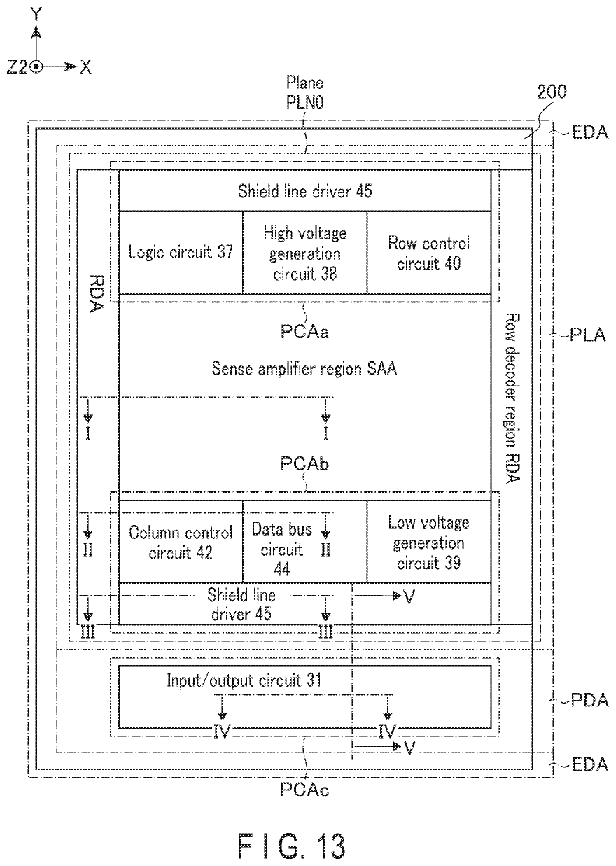

FIG. 13 is a planar view showing an example of a planar layout of the peripheral circuit of the circuit chip 200. FIG. 13 shows the plane PLN0 and the peripheral circuit region PCAc corresponding to the plane PLN0.

The peripheral circuit region PCAa includes, for example, the logic circuit 37, the high voltage generation circuit 38, the row control circuit 40, and the shield line driver 45. The logic circuit 37, the high voltage generation circuit 38, and the row control circuit 40 are arranged side by side in the X direction, for example. The logic circuit 37, the high voltage generation circuit 38, and the row control circuit 40 are provided between the sense amplifier region SAA and the shield line driver 45, for example. In other words, the shield line driver 45 is provided in a position further away from the sense amplifier region SAA.

The peripheral circuit region PCAb includes, for example, the column control circuit 42, the data bus circuit 44, the low voltage generation circuit 39, and the shield line driver 45. The column control circuit 42, the data bus circuit 44, and the low voltage generation circuit 39 are arranged side by side in the X direction, for example. The column control circuit 42, the data bus circuit 44, and the low voltage generation circuit 39 are provided between, for example, the sense amplifier region SAA and the shield line driver 45.

The peripheral circuit region PCAc includes, for example, the input/output circuit 31.

### 1.1.11 Cross-Sectional Structure of NAND Flash Memory

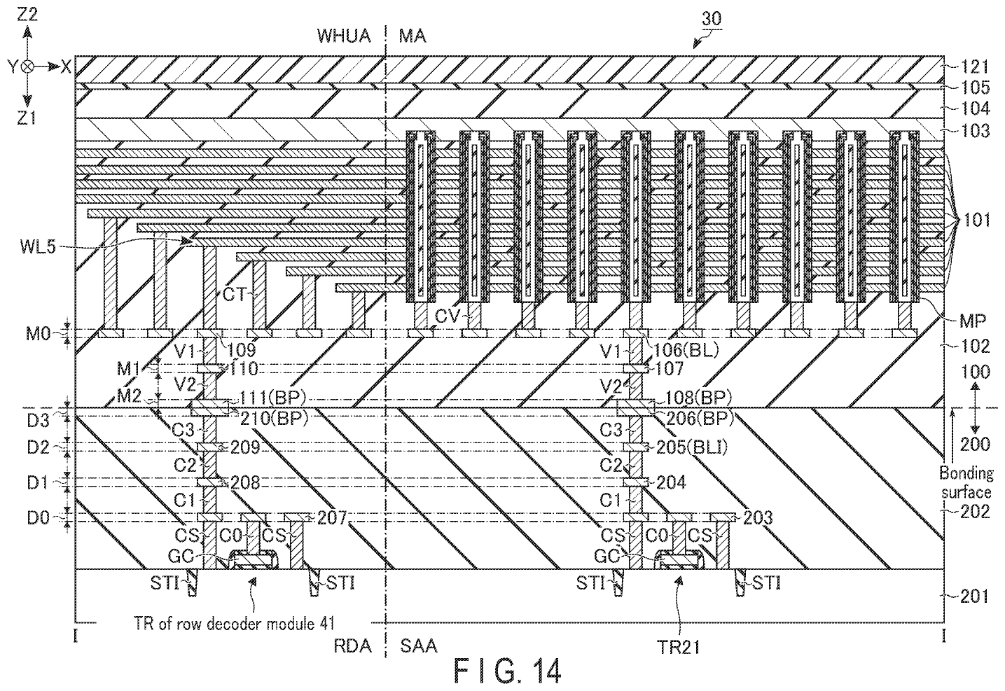

A cross-sectional structure of the NAND flash memory 30 will be described. Hereinafter, the cross-sectional view taken along the line I-I of FIG. 11 and FIG. 13, the cross-sectional view taken along the line II-II of FIG. 11 and FIG. 13, the cross-sectional view taken along the line III-III of FIG. 11 and FIG. 13, the cross-sectional view taken along the line IV-IV of FIG. 11 and FIG. 13, and the cross-sectional view taken along the line V-V of FIG. 11 and FIG. 13 will be described in this order. FIG. 14 is a cross-sectional view taken along the line I-I of FIG. 11 and FIG. 13 and showing an example of a cross-sectional structure of the NAND flash memory 30. FIG. 14 shows the bonded structure in which the array chip 100 and the circuit chip 200 are bonded to each other. First, the array chip 100 will be described.

As shown in FIG. 14, the array chip 100 includes a plurality of interconnect layers 101, an insulating layer 102, an interconnect layer 103, insulating layers 104 and 105, a passivation layer 121, a plurality of contact plugs CV, CT, V1, and V2, interconnect layers 106, 107, 109, and 110, bonding pads 108 and 111, and a plurality of memory pillars MP.

In the cell region MA, the plurality of (10) interconnect layers 101 are stacked with a space therebetween in the Z direction. The interconnect layer 101 functions as the word line WL and the select gate lines SGD and SGS. The insulating layer 102 is provided between the interconnect layers 101. The insulating layer 102 is provided on the uppermost interconnect layer 101. The insulating layer 102 is provided below the lowermost interconnect layer 101. The interconnect layers 101 are formed of a conductive material and may be, for example, a metallic material, a p-type semiconductor, or an n-type semiconductor. The insulating layer 102 is formed of an insulating material and includes, for example, silicon oxide (SiO).

The interconnect layer 103 is provided on the uppermost insulating layer 102. The interconnect layer 103 is formed into, for example, a plate shape extending on the XY plane, and functions as the source line SL. The interconnect layer 103 is formed of a conductive material and includes, for example, silicon doped with phosphorus, tungsten silicide, and titanium nitride.

The insulating layer 104 is provided on the interconnect layer 103. The insulating layer 104 is formed of an insulating material and includes, for example, silicon oxide.

The insulating layer 105 is provided on the insulating layer 104. The insulating layer 105 is formed of an insulating material and includes, for example, silicon oxide.

The passivation layer 121 is formed on the insulating layer 105. The passivation layer 121 includes, for example, polyimide.

The plurality of memory pillars MP extend in the Z direction and penetrate the plurality of interconnect layers 101 and the insulating layer 102. The end portion in the 22 direction of the memory pillar MP is in contact with the interconnect layer 103. The memory pillar MP includes, for example, a semiconductor film and an insulating film. The semiconductor film is in contact with the interconnect layer 103. One memory pillar MP corresponds to one NAND string NS. The memory pillars MP will be described later in detail. The end portion in the Z1 direction of the memory pillar MP is coupled to the interconnect layer 106 via a contact plug CV. The interconnect layer 106 electrically coupled to the memory pillar MP functions as the bit line BL. The contact plug CV is formed of a conductive material and may be, for example, a metallic material, a p-type semiconductor, or an n-type semiconductor. The interconnect layer 106 is formed of a conductive material and may be, for example, a metallic material, a p-type semiconductor, or an n-type semiconductor.

The interconnect layer 106 is electrically coupled to the bonding pad 108 via the contact plug V1, the interconnect layer 107, and the contact plug V2, for example. The bonding pad 108 is for use in coupling to the circuit chip 200. The contact plugs V1 and V2 are formed of a conductive material and may be, for example, a metallic material, a p-type semiconductor, or an n-type semiconductor. The interconnect layer 107 is formed of a conductive material and may be, for example, a metallic material, a p-type semiconductor, or an n-type semiconductor. The bonding pad 108 is formed of a conductive material and may be, for example, a metallic material. The bonding pad 108 includes, for example, copper (Cu).

In the word line hookup region WHUA, terrace portions of the plurality of interconnect layers 101 are provided in a stepwise manner. The plurality of contact plugs CT are respectively provided on the terrace portions of the interconnect layers 101 in the Z1 direction. The contact plugs CT are coupled to the interconnect layer 109 in the Z1 direction. The interconnect layer 109 is electrically coupled to the bonding pad 111 via the contact plug V1, the interconnect layer 101, and the contact plug V2, for example. The bonding pad 111 is for use in coupling to the circuit chip 200. The contact plug CT is formed of a conductive material and may be, for example, a metallic material, a p-type semiconductor, or an n-type semiconductor. The interconnect layers 109 and 110 are formed of a conductive material and may be, for example, a metallic material, a p-type semiconductor, or an n-type semiconductor. The bonding pad 111 is formed of a conductive material and may be, for example, a metallic material. The bonding pad 111 includes, for example, copper.

Hereinafter, the interconnect layer provided with the interconnect layers 106 and 109 will be also referred to as an “interconnect layer M0”. The interconnect layer provided with the interconnect layers 107 and 110 will be also referred to as an “interconnect layer M1”. The interconnect layer provided with the bonding pads 108 and 111 will be also referred to as an “interconnect layer M2”. The number of interconnect layers provided in the array chip 100 may be freely designed.

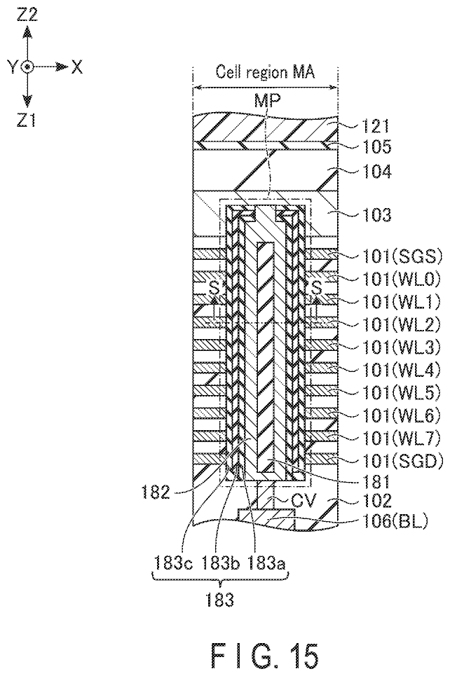

FIG. 15 is a cross-sectional view of the memory pillar MP and its vicinity within the cell region MA of the array chip 100. Meanwhile, FIG. 15 omits the contact plugs V1 and V2, the interconnect layer 107, and the bonding pad 108.

A portion in which the memory pillar MP intersects the interconnect layer 101 (select gate line SGS) functions as a select transistor ST2. A portion in which the memory pillar MP intersects one of the interconnect layers 101 (word lines WL0 to WL7) functions as one memory cell transistor MC. A portion in which the memory pillar MP intersects the interconnect layer 101 (select gate line SGD) functions as a select transistor ST1.

The memory pillar MP includes, for example, a core film 181, a semiconductor film 182, and a stacked film 183.

The core film 181 extends in the Z direction. For example, in the Z1 direction, the lower end of the core film 181 is located below the lowermost interconnect layer 101, and the upper end of the core film 181 is located below the interconnect layer 103. The core film 181 is formed of an insulating material and includes, for example, silicon oxide.

A semiconductor film 182 covers the periphery of the core film 181. At the upper end in the Z1 direction of the memory pillar MP, a part of the semiconductor film 182 is in contact with the interconnect layer 103. The semiconductor film 182 functions as a channel for each of the memory cell transistor MC and the select transistors ST1 and ST2. The semiconductor film 182 includes, for example, silicon.

The stacked film 183 covers the side and bottom surfaces of the semiconductor film 182 except for the portion in which the semiconductor film 182 and the interconnect layer 103 are in contact with each other. The stacked film 183 is, for example, a stacked film in which a first insulating layer 183a, a second insulating layer 183b, and a third insulating layer 183c are stacked in this order.

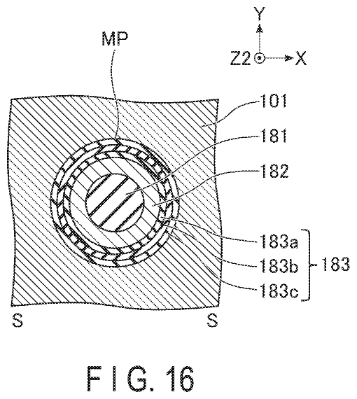

FIG. 16 is a cross-sectional view taken along the line S-S of FIG. 15 and shows an example of the cross-sectional structure of the memory pillar MP. Specifically, FIG. 16 shows a cross-sectional structure of the memory pillar MP in a layer that is parallel to the XY plane and includes the interconnect layer 101.

The first insulating layer 183a covers the periphery of the semiconductor film 182. The first insulating layer 183a functions as a tunnel insulating film of the memory cell transistor MC. The first insulating layer 183a is formed of an insulating material and includes, for example, silicon oxide and silicon oxynitride. The second insulating layer 183b covers the periphery of the first insulating layer 183a. The second insulating layer 183b functions as a charge storage layer of the memory cell transistor MC. The second insulating layer 183b is formed of an insulating material and includes, for example, silicon nitride. The third insulating layer 183c covers the periphery of the second insulating layer 183b. The third insulating layer 183c functions as a block insulating film of the memory cell transistor MC. The third insulating layer 183c is formed of an insulating material and includes, for example, silicon oxide and aluminum oxide. The interconnect layer 101 covers the periphery of the third insulating layer 183c.

Next, the circuit chip 200 will be described.

As shown in FIG. 14, the circuit chip 200 includes a semiconductor substrate 201, an insulating layer 202, interconnect layers GC, 203 to 205 and 207 to 209, contact plugs CS and C0 to C3, and bonding pads 206 and 210. In FIG. 14, a configuration corresponding to the transistor TR21 within the sense amplifier region SAA, and a configuration corresponding to the transistor TR of the row decoder module 41 within the row decoder region RDA are extracted and shown.

The semiconductor substrate 201 is for use in formation of the circuit chip 200 and includes, for example, p-type impurities. Furthermore, the semiconductor substrate 201 includes a plurality of well regions (not shown). For example, a transistor is formed in each of the well regions. The plurality of well regions are separated by, for example, an ST1 (Shallow Trench Isolation). The insulating layer 202 is provided on the semiconductor substrate 201. The insulating layer 202 is formed of an insulating material and includes, for example, silicon oxide.

In the sense amplifier region SAA, the interconnect layer GC is provided on the semiconductor substrate 201 with a gate insulating film intervening therebetween. In the sense amplifier region SAA, the interconnect layer GC is used as, for example, a gate electrode of the transistor TR21 included the sense amplifier 43. The contact plug C0 is provided on the interconnect layer GC in such a manner as to correspond to the gate of the transistor TR21. Two contact plugs CS are provided on the semiconductor substrate 201 in such a manner as to respectively correspond to a source and a drain of the transistor TR21. For example, the upper surface of the contact plug CS is flush with the upper surface of the contact plug C0.

Furthermore, in the sense amplifier region SAA, one interconnect layer 203 is provided on each of the contact plug CS and the contact plug C0. The contact plug C1 is provided on the interconnect layer 203. The interconnect layer 204 is provided on the contact plug C1. The contact plug C2 is provided on the interconnect layer 204. The interconnect layer 205 is provided on the contact plug C2. The interconnect layer 205 functions as the interconnect BLI included in the sense amplifier 43. The contact plug C3 is provided on the interconnect layer 205. A bonding pad 206 is provided on the contact plug C3. The bonding pad 206 is for use in coupling to the array chip 100. The bonding pad 206 is bonded to the bonding pad 108 of the array chip 100. Although not shown, the sense amplifier region SAA includes a plurality of transistors having similar structures to that of the transistor TR21. The interconnect layers 203 to 205 are formed of a conductive material and may be, for example, a metallic material, a p-type semiconductor, or an n-type semiconductor. The contact plugs CS and C0 to C3 are formed of a conductive material and may be, for example, a metallic material, a p-type semiconductor, or an n-type semiconductor. The bonding pad 206 is formed of a conductive material and may be, for example, a metallic material. The bonding pad 206 includes, for example, copper.

In the row decoder region RDA, the interconnect layer GC is provided on the semiconductor substrate 201 with a gate insulating film intervening therebetween. The interconnect layer GC in the row decoder region RDA is used as, for example, a gate electrode of the transistor TR included in the row decoder module 41. The contact plug C0 is provided on the interconnect layer GC in such a manner as to correspond to a gate of the aforementioned transistor TR. Two contact plugs CS are provided on the semiconductor substrate 201 in such a manner as to respectively correspond to a source and a drain of the transistor TR.

Furthermore, in the row decoder region RDA, one interconnect layer 207 is provided on each of the contact plug CS and the contact plug C0. The contact plug C1 is provided on the interconnect layer 207. The interconnect layer 208 is provided on the contact plug C1. The contact plug C2 is provided on the interconnect layer 208. The interconnect layer 209 is provided on the contact plug C2. The contact plug C3 is provided on the interconnect layer 209. The bonding pad 210 is provided on the contact plug C3. The bonding pad 210 is for use in coupling to the array chip 100. The bonding pad 210 is bonded to the bonding pad 111 of the array chip 100. Although not shown, the row decoder region RDA includes a plurality of transistors having similar structures to that of the transistor TR of the row decoder module 41. The interconnect layers 207 to 209 are formed of a conductive material and may be, for example, a metallic material, a p-type semiconductor, or an n-type semiconductor. The bonding pad 210 is formed of a conductive material and may be, for example, a metallic material. The bonding pad 210 includes, for example, copper.

Hereinafter, the interconnect layer provided with the interconnect layers 203 and 207 will be also referred to as an “interconnect layer DO”. The interconnect layer provided with the interconnect layers 204 and 208 will be also referred to as an “interconnect layer D1”. The interconnect layer provided with the interconnect layers 205 and 209 will be also referred to as an “interconnect layer D2”. The interconnect layer provided with the bonding pads 206 and 210 will be also referred to as an “interconnect layer D3”. The number of interconnect layers provided in the circuit chip 200 may be freely designed.

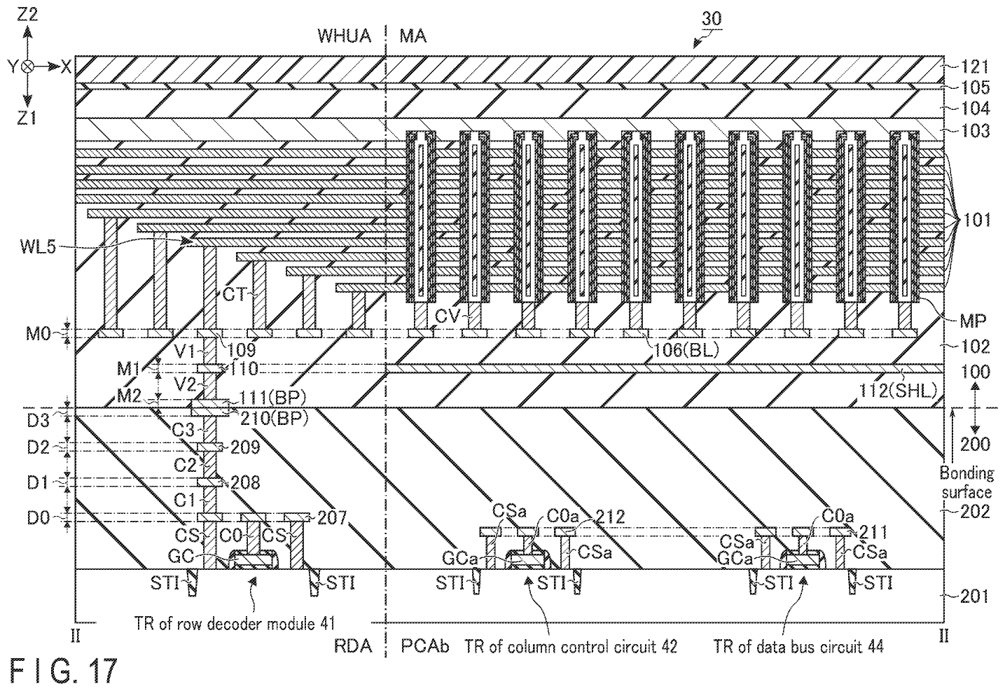

FIG. 17 is a cross-sectional view taken along the line II-II of FIG. 11 and FIG. 13 and showing an example of a cross-sectional structure of the NAND flash memory 30.

As shown in FIG. 17, the array chip 100 includes the interconnect layer 112. An upper cross-sectional structure of the interconnect layer 106 in the cell region MA of the array chip 100 is similar to an upper cross-sectional structure of the interconnect layer 106 in the cell region MA shown in FIG. 14. A cross-sectional structure of the word line hookup region WHUA in the array chip 100 is similar to a cross-sectional structure of the word line hookup region WHUA shown in FIG. 14.

In the cell region MA, the interconnect layer 112 is provided between the bonding surface and the memory cell array 36. More precisely, the interconnect layer 112 is provided between the bonding surface and the interconnect layer 106. In other words, the interconnect layer 112 faces the interconnect layer 106 (bit line BL) in the Z direction (the direction from the bonding surface to the memory cell array 36). The interconnect layer 112 is provided in the same layer as the interconnect layer M1. The interconnect layer 112 is formed into, for example, a plate shape extending on the XY plane, and functions as the shield line SHL.

As shown in FIG. 17, the circuit chip 200 includes interconnect layers GCa, 211, and 212, and contact plugs CSa and C0a. In FIG. 17, a configuration corresponding to the transistor TR of the data bus circuit 44 in the peripheral circuit region PCAb, a configuration corresponding to the transistor TR of the column control circuit 42 in the peripheral circuit region PCAb, and a configuration corresponding to the transistor TR of the row decoder module 41 in the row decoder region RDA are extracted and shown. A cross-sectional structure of the row decoder region RDA of the circuit chip 200 is similar to a cross-sectional structure of the row decoder region RDA shown in FIG. 14.

In the peripheral circuit region PCAb, an interconnect layer GCa is provided on the semiconductor substrate 201 with a gate insulating film intervening therebetween. The interconnect layer GCa in the peripheral circuit region PCAb is used as, for example, a gate electrode of each of the transistor TR included in the column control circuit 42 and the transistor TR included in the data bus circuit 44. The contact plug C0a is provided on the interconnect layer GCa in such a manner as to correspond to the gate of each of the aforementioned transistors TR. Two contact plugs CSa are provided on the semiconductor substrate 201 in such a manner as to respectively correspond to a source and a drain of each of the aforementioned transistors TR. For example, the upper surface of the contact plug CSa is flush with the upper surface of the contact plug C0a.

Furthermore, in the peripheral circuit region PCAb, one interconnect layer 211 is provided on each of the contact plug CSa and the contact plug C0a corresponding to the transistor TR of the data bus circuit 44. One interconnect layer 212 is provided on each of the contact plug CSa and the contact plug C0a corresponding to the transistor TR of the column control circuit 42. The interconnect layers 211 and 212 are formed of a conductive material and may be, for example, a metallic material, a p-type semiconductor, or an n-type semiconductor. The contact plugs CSa and C0a are formed of a conductive material and may be, for example, a metallic material, a p-type semiconductor, or an n-type semiconductor.

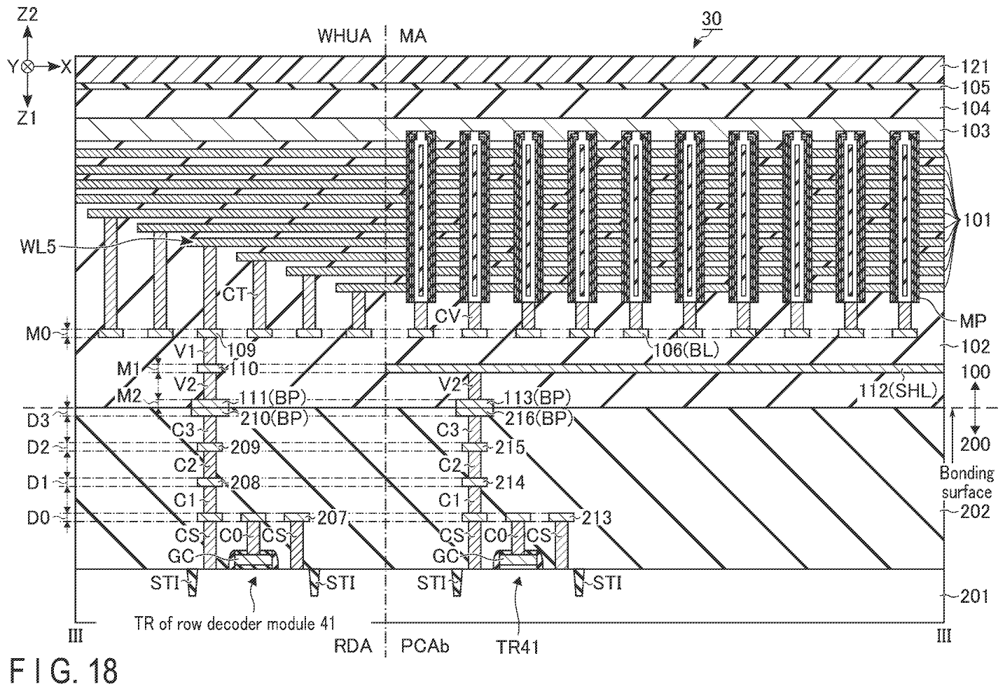

FIG. 18 is a cross-sectional view taken along the line III to III of FIG. 11 and FIG. 13 and showing an example of a cross-sectional structure of the NAND flash memory 30.

As shown in FIG. 18, the array chip 100 includes a bonding pad 113. An upper cross-sectional structure of interconnect layer 112 in the cell region MA of the array chip 100 is similar to an upper cross-sectional structure of the interconnect layer 112 in the cell region MA shown in FIG. 17. A cross-sectional structure of the word line hookup region WHUA in the array chip 100 is similar to a cross-sectional structure of the word line hookup region WHUA shown in FIG. 14.

In the cell region MA, the interconnect layer 112 is electrically coupled to the bonding pad 113 with the contact plug V2 intervening therebetween. The bonding pad 113 is for use in coupling to the circuit chip 200. The bonding pad 113 is formed of a conductive material and may be, for example, a metallic material. The bonding pad 113 includes, for example, copper.

As shown in FIG. 18, the circuit chip 200 includes interconnect layers 213 to 215 and a bonding pad 216. In FIG. 18, a configuration corresponding to the transistor TR41 of the shield line driver 45 within the peripheral circuit region PCAb, and a configuration corresponding to the transistor TR of the row decoder module 41 within the row decoder region RDA are extracted and shown. A cross-sectional structure of the row decoder region RDA of the circuit chip 200 is similar to a cross-sectional structure of the row decoder region RDA shown in FIG. 14.

In the peripheral circuit region PCAb, the interconnect layer GC is provided on the semiconductor substrate 201 with a gate insulating film intervening therebetween. The interconnect layer GC within the peripheral circuit region PCAb is used as, for example, a gate electrode of the transistor TR41 included in the shield line driver 45. The contact plug C0 is provided on the interconnect layer GC in such a manner as to correspond to the gate of the transistor TR41. Two contact plugs CS are provided on the semiconductor substrate 201 in such a manner as to respectively correspond to a source and a drain of the transistor TR41.

Furthermore, in the peripheral circuit region PCAb, one interconnect layer 213 is provided on each of the contact plug CS and the contact plug C0. The contact plug C1 is provided on the interconnect layer 213. An interconnect layer 214 is provided on the contact plug C1. The contact plug C2 is provided on the interconnect layer 214. The interconnect layer 215 is provided on the contact plug C2. The contact plug C3 is provided on the interconnect layer 215. The bonding pad 216 is provided on the contact plug C3. The bonding pad 216 is for use in coupling to the array chip 100. The bonding pad 216 is bonded to the bonding pad 113 of the array chip 100. Although not shown, the peripheral circuit region PCAb includes a plurality of transistors having similar structures to that of the transistor TR41. The interconnect layers 213 to 215 are formed of a conductive material and may be, for example, a metallic material, a p-type semiconductor, or an n-type semiconductor. The bonding pad 216 is formed of a conductive material and may be, for example, a metallic material. The bonding pad 216 includes, for example, copper.

With the configuration described above, a voltage is applied by the shield line driver 45 to the interconnect layer 112 provided in the cell region MA (plane region PLA). A voltage to be applied is, for example, the ground voltage VSS.

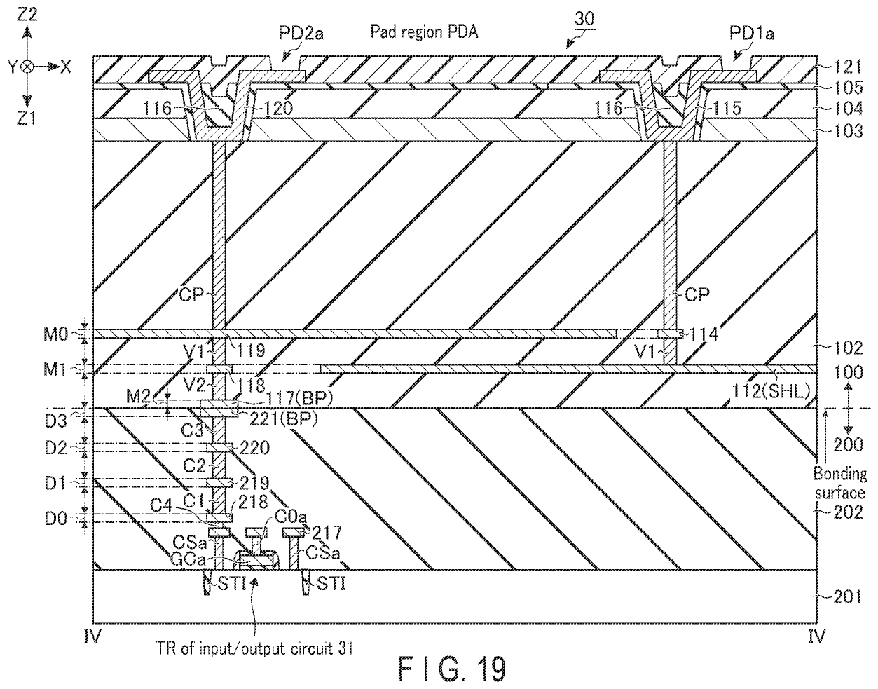

FIG. 19 is a cross-sectional view taken along the line IV to IV of FIG. 11 and FIG. 13 and showing an example of a cross-sectional structure of the NAND flash memory 30.

As shown in FIG. 19, the array chip 100 includes a bonding pad 117, interconnect layers 114, 115, and 118 to 120, a contact plug CP, and an insulating layer 116.

In the pad region PDA, the insulating layer 105, the interconnect layers 115 and 120, the insulating layer 116, and the passivation layer 121 are provided on the interconnect layer 103.

The interconnect layer 115 is coupled to the interconnect layer 112 with the contact plug CP, the interconnect layer 114, and the contact plug V1 intervening therebetween. In the 22 direction, the insulating layer 116 is provided on a part of the interconnect layer 115. The passivation layer 121 is provided on a part of the interconnect layer 115 and the entirety of the insulating layer 116. In other words, a part of the interconnect layer 115 in the Z2 direction is not covered with the passivation layer 121. The aforementioned part functions as the pad PD1a. A part of the interconnect layer 115 in the Z1 direction is in contact with the insulating layer 105. A part of the insulating layer 105 is in contact with the interconnect layer 103 and the insulating layers 102 and 104.

With the configuration described above, the interconnect layer 112 provided in the pad region PDA (non-plane region) is electrically coupled to the pad PD1a. In this manner, a voltage is externally supplied via the pad PD1a to the interconnect layer 112 provided in the pad region PDA. A voltage to be supplied is, for example, the voltage VCC.

The interconnect layer 119 is formed into, for example, a plate shape extending on the XY plane.

The interconnect layer 120 is coupled to the bonding pad 117 with the contact plug CP, the interconnect layer 119, the contact plug V1, the interconnect layer 118, and the contact plug V2 intervening therebetween. In the Z2 direction, the insulating layer 116 is provided on a part of the interconnect layer 120. The passivation layer 121 is provided on a part of the interconnect layer 120 and the entirety of the insulating layer 116. In other words, a part of the interconnect layer 120 in the Z2 direction is not covered with the passivation layer 121. The aforementioned part functions as the pad PD2a. A part of the interconnect layer 120 in the Z1 direction is in contact with the insulating layer 105. The bonding pad 117 is for use in coupling to the circuit chip 200.

The interconnect layers 114, 115 and 118 to 120 are formed of a conductive material and may be, for example, a metallic material, a p-type semiconductor, or an n-type semiconductor. The contact plug CP is formed of a conductive material and may be, for example, a metallic material, a p-type semiconductor, or an n-type semiconductor. The insulating layer 116 is formed of an insulating material and includes, for example, silicon oxide. The bonding pad 117 is formed of a conductive material and may be, for example, a metallic material. The bonding pad 117 includes, for example, copper.

The interconnect layer 112 is spaced apart from the interconnect layer 118 in the X direction. The interconnect layer 112 does not overlap the pad PD2a in the Z direction. The interconnect layer 119 is spaced apart from the interconnect layer 114 in the X direction.

As shown in FIG. 19, the circuit chip 200 includes interconnect layers 217 to 220 and a bonding pad 221. In FIG. 19, a configuration corresponding to the transistor TR of the input/output circuit 31 within the peripheral circuit region PCAc is extracted and shown.

In the pad region PDA (peripheral circuit region PCAc), the interconnect layer GCa is provided on the semiconductor substrate 201 with a gate insulating film intervening therebetween. The interconnect layer GCa within the peripheral circuit region PCAc is used as, for example, a gate electrode of the transistor TR included in the input/output circuit 31. The contact plug C0a is provided on the interconnect layer GCa in such a manner as to correspond to a gate of the aforementioned transistor TR. Two contact plugs CSa are provided on the semiconductor substrate 201 in such a manner as to respectively correspond to a source and a drain of the transistor TR.

Furthermore, in the peripheral circuit region PCAc, one interconnect layer 217 is provided on each of the contact plug CSa and the contact plug C0a. A contact plug C4 is provided on the interconnect layer 217. An interconnect layer 218 is provided on the contact plug C4. A contact plug C1 is provided on an interconnect layer 218. The interconnect layer 219 is provided on the contact plug C1. The contact plug C2 is provided on the interconnect layer 219. The interconnect layer 220 is provided on the contact plug C2. The contact plug C3 is provided on the interconnect layer 220. A bonding pad 221 is provided on the contact plug C3. The bonding pad 221 is for use in coupling to the array chip 100. The bonding pad 221 is bonded to the bonding pad 117 of the array chip 100. The interconnect layers 217 to 220 are formed of a conductive material and may be, for example, a metallic material, a p-type semiconductor, or an n-type semiconductor. The bonding pad 221 is formed of a conductive material and may be, for example, a metallic material. The bonding pad 221 includes, for example, copper.

With the configuration described above, a voltage is externally supplied via the pad PD2a to the input/output circuit 31 provided in the pad region PDA. A voltage to be supplied is, for example, the voltage VCCQ or VCCQL.

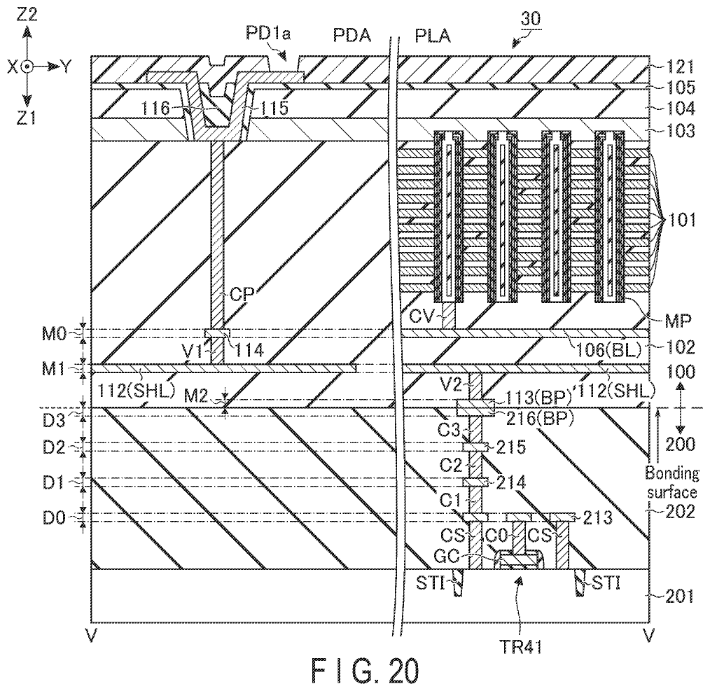

FIG. 20 is a cross-sectional view taken along the line V to V of FIG. 11 and FIG. 13 and showing an example of a cross-sectional structure of the NAND flash memory 30.

As shown in FIG. 20, a cross-sectional structure of plane region PLA of the array chip 100 is similar to that of the cell region MA shown in FIG. 18. A cross-sectional structure of the pad region PDA of the circuit chip 200 is similar to that of the pad region PDA shown in FIG. 19.

The interconnect layer 112 within the pad region PDA is spaced apart from the interconnect layer 112 within the plane region PLA in the Y direction. In other words, the interconnect layer 112 is disconnected between the plane region PLA and the non-plane region. That is, the interconnect layer 112 within the non-plane region is not electrically coupled to the interconnect layer 112 within the plane region PLA. The interconnect layer 114 is spaced apart from the interconnect layer 106 in the Y direction.

### 1.2 Advantageous Effect of Present Embodiment

The NAND flash memory 30 according to the first embodiment can suppress noise propagation. This advantageous effect will be described below.

In the bonding structure in which the array chip 100 and the circuit chip 200 are bonded together, in the vicinity of the bonding surface, for example, the bit line BL of the array chip 100 provided in the plane region PLA faces a signal line such as the sense amplifier 43, etc. of the circuit chip 200 in the Z direction (vertical direction). With the bit line BL facing the aforementioned signal line, noise may be caused by application of a voltage to the bit line BL and the signal line and be propagated therebetween. Thus, the effect of suppressing noise propagation between the bit line BL and the signal line can be expected by, for example, providing the shield line SHL between the bit line BL and the signal line.

On the other hand, in a case where the shield line SHL is provided all over the XY plane of the NAND flash memory 30 including the pad region PDA and the end region EDA in addition to the plane region PLA, noise caused in the bit line BL may be propagated to the input/output circuit 31, etc., within the pad region PDA via the shield line SHL to adversely affect the operation of the input/output circuit 31, etc., for example. Furthermore, noise caused in the input/output circuit 31, etc., may also be propagated to the bit line BL via the shield line SHL to adversely affect the write operation, etc.

In view of this, in the NAND flash memory 30 according to the present embodiment, the shield line SHL (interconnect layer 112) is provided between the bonding surface and the bit line BL. This can suppress noise propagation between the array chip 100 and the circuit chip 200 in the Z direction. Furthermore, in the NAND flash memory 30 according to the present embodiment, the shield line SHL is disconnected between the plane region PLA and the non-plane region. This can suppress noise propagation between plane region PLA and the non-plane region.

Furthermore, in the NAND flash memory 30 according to the present embodiment, the voltage VCC or VCCQ/VCCQL is supplied from the pad PD1 to the shield line SHL provided in the non-plane region. This causes capacitance coupling between the shield line SHL and an interconnect facing thereto (for example, the interconnect layer 119) in the Z direction, thereby functioning as decoupling capacitors. Accordingly, a charged electric charge can be supplied at the time when power supply varies. This can realize stabilization of a power supply VCC or VCCQ/VCCQL.

### 1.3 First Modification

The NAND flash memory 30 according to a first modification of the first embodiment is different from that of the first embodiment in terms of the planar layout of the shield line SHL within the array chip 100. Hereinafter, with respect to the NAND flash memory 30 according to the first modification of the first embodiment, the difference from the first embodiment will be described.

### 1.3.1 Layout of Shield Line

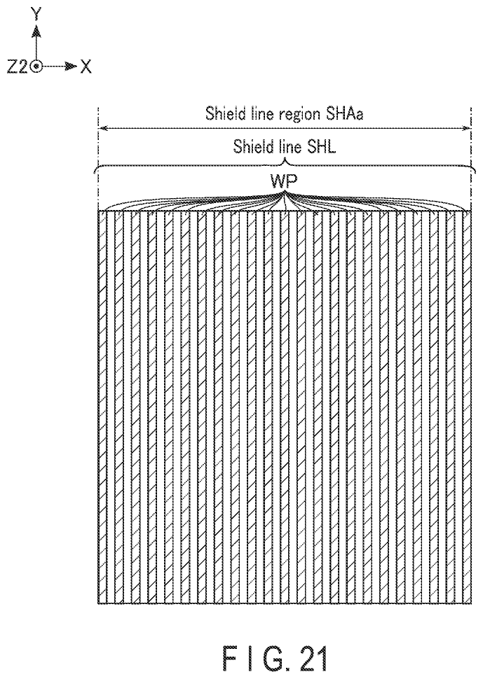

FIG. 21 is a planar view showing an example of a planar layout of the shield lines SHL within the array chip 100. FIG. 21 shows the shield line region SHAa within the plane PLN0.

As shown in FIG. 21, the shield line region SHAa is provided with the shield line SHL. The shield line SHL includes, for example, a plurality of interconnect portions WP. The plurality of interconnect portions WP are each formed into, for example, a line shape extending in the Y direction and are spaced apart from each other in the X direction. As with the shield line region SHAa, the shield line SHL including the plurality of interconnect portions WP is arranged in the shield line region SHAb within the plane PLN0 and the shield line region SHAc corresponding to the plane PLN0. Meanwhile, in the shield line region SHAc, the shield line SHL is provided in such a manner as to avoid overlap with the plurality of pads PD2a in the Z direction, for example.

In the shield line regions SHAa, SHAb, and SHAc, the shield line SHL is provided in a layer between the bonding surface and the bit line BL as in FIG. 17 described in the first embodiment. As in FIG. 11 described in the first embodiment, the shield line SHL within the shield line region SHAa is spaced apart from the shield line SHL within the shield line region SHAb in the Y direction. As in FIG. 11 described in the first embodiment, the shield line SHL within the shield line region SHAb is spaced apart from the shield line SHL within the shield line region SHAC in the Y direction.

In the shield line regions SHAa, SHAb, and SHAc, the plurality of interconnect portions WP included in the shield line SHL may be each formed into a line shape extending in the X direction and may be spaced apart from each other in the Y direction. The arrangement described above can suppress noise propagation between the shield line SHL and an interconnect (e.g., the bit line BL) facing thereto in the Z direction, as compared to the arrangement in which, for example, the interconnect portions of the shield line SHL extends in the X direction to stride over the bit lines BL.

### 1.3.2 Advantageous Effect of Present Modification

The present modification produces advantageous effects similar to those of the first embodiment.

### 1.4 Second Modification

The NAND flash memory 30 according to a second modification of the first embodiment is different from that of the first embodiment in terms of the planar layout of the array chip 100. Hereinafter, with respect to the NAND flash memory 30 according to the second modification of the first embodiment, the difference from the first embodiment will be described.

### 1.4.1 Layout of Array Chip

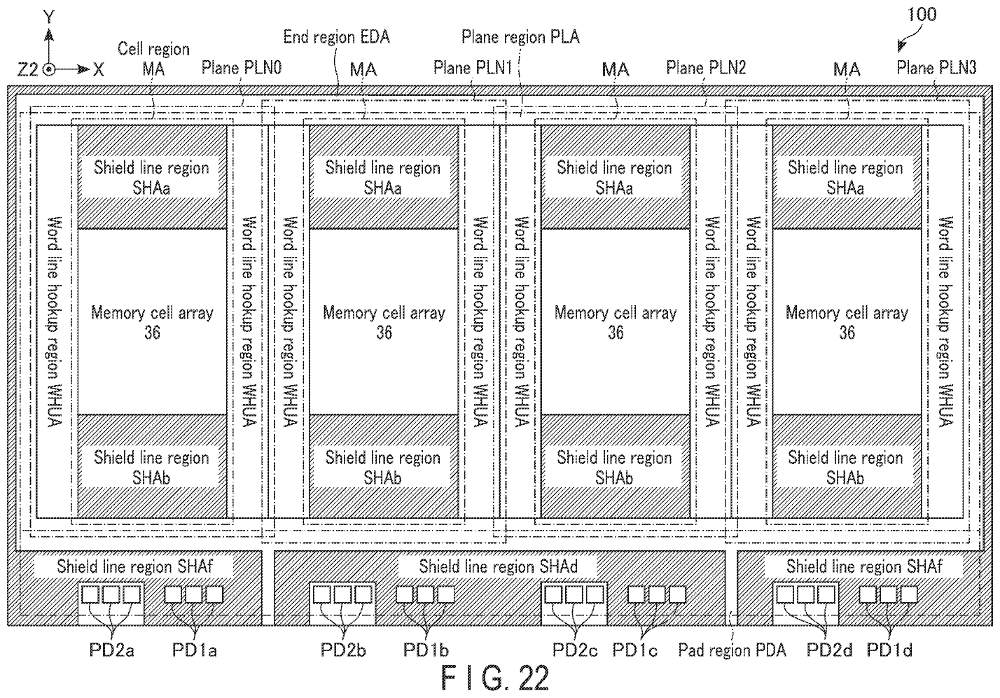

A planar layout of the array chip 100 will be described with reference to FIG. 22. FIG. 22 is a planar view showing an example of a planar layout of the array chip 100. Meanwhile, the plane region PLA, the planes PLN0 to PLN3, the pad region PDA, and the end region EDA shown in FIG. 22 respectively correspond to the plane region PLA, the planes PLN0 to PLN3, the pad region PDA, and the end region EDA shown in FIG. 9. That is, the array chip 100 includes the plane region PLA, the pad region PDA, and the end region EDA.

The array chip 100 includes shield line regions SHAd and SHAf within the pad region PDA and the end region EDA. The shield line region SHAd is similar to that shown in FIG. 10 described in the first embodiment. The shield line region SHAf is a region including the shield line regions SHAc and SHAe shown in FIG. 10 described in the first embodiment and the left, upper, and right ends of the array chip 100. In other words, the shield line region SHAf is a region covering the left, upper, and right ends of the array chip 100. That is, the shield line SHL provided in the shield line SHAf covers the left, upper, and right ends of the non-plane region.

### 1.4.2 Advantageous Effect of Present Modification

The present modification produces advantageous effects similar to those of the first embodiment.

### 2. Second Embodiment

The NAND flash memory 30 according to a second embodiment is different from that of the first embodiment in terms of controlling a voltage to be supplied to the shield line SHL within the plane region PLA during the write operation. Hereinafter, with respect to the NAND flash memory 30 according to the second embodiment, the difference from the first embodiment will be described.

### 2.1 Data Storage Method

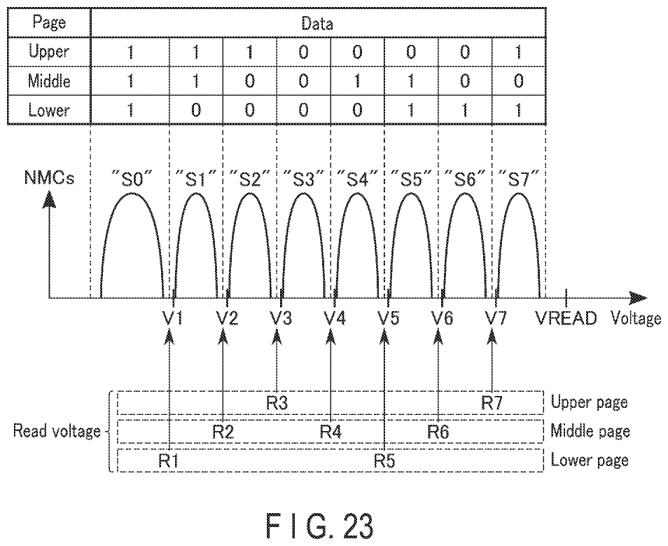

An example of a data storage method will be described with reference to FIG. 23. FIG. 23 is a conceptional diagram showing an example of a data storage method. FIG. 23 shows an example of threshold voltage distributions of the memory cell transistors MC, data allocation, and voltages for use in a data read operation. In the threshold voltage distribution chart to be referred to below, the label “NMCs” in the vertical axis indicates the number of memory cell transistors MC, and voltages in the lateral axis show voltages to be applied to gates of the memory cell transistors MC.

As shown in FIG. 23, in a case of one memory cell transistor being a TLC configured to store 3-bit data, the threshold voltage distribution formed by the plurality of memory cell transistors MC included in the cell unit CU can take eight types of states. Hereinafter, these states of eight types will be referred to as an “S0”, state, an “S1” state, an “S2” state, an “S3” state, an “S4” state, an “S5” state, an “S6” state, and an “S7” state in the ascending order of threshold voltage.

In a case of the memory cell transistor MC being in an erase state, a threshold voltage of the memory cell transistor MC is included in the “S0” state. In a case of the memory cell transistor MC having data written therein, a threshold voltage of the memory cell transistor MC is included in any one of the “S0” to “S7” states. Different 3-bit data is allocated to each of the “S0” to “S7” states. It is preferable that data allocation be set such that only 1-bit data differs between two neighboring states. Listed below is an example of data allocation to the eight states.

“S0” state: “111 (upper bit/middle bit/lower bit)” data
“S1” state: “110” data
“S2” state: “100” data
“S3” state: “000” data
“S4” state: “010” data
“S5” state: “011” data
“S6” state: “001” data
“S7” state: “101” data

A verify voltage for use in checking of a data write operation and a read voltage for use in a data read operation are set between adjacent states. Specifically, a verify voltage V1 and a read voltage R1 are set between the “S0” and “S1” states. A verify voltage V2 and a read voltage R2 are set between the “S1” and “S2” states. A verify voltage V3 and a read voltage R3 are set between the “S2” and “S3” states. A verify voltage V4 and a read voltage R4 are set between the “S3” and “S4” states. A verify voltage V5 and a read voltage R5 are set between the “S4” and “S5” states. A verify voltage V6 and a read voltage R6 are set between the “S5” and “S6” states. A verify voltage V7 and a read voltage R7 are set between the “S6” and “S7” states. It is preferable that the verify voltages V1 to V7 be set higher than the read voltages R1 to R7, respectively.

The verify voltages V1 to V7 are respectively associated with the “S1” to “S7” states. In the write operation, the NAND flash memory 30 checks whether or not a threshold voltage of the memory cell transistor MC in which data is desired to be stored has exceeded a verify voltage associated with the aforementioned data through the read operation using a verify voltage (hereinafter referred to as a “program verify operation”). Upon detection of the fact that the threshold voltage of the memory cell transistor MC concerned has exceeded the verify voltage associated with the aforementioned data, the sequencer 35 completes the data write operation on the memory cell transistor MC concerned.

The read voltage R1 is for use in distinction between the “S0” state and the “S1” or higher state. The read voltage R2 is for use in distinction between the “S1” or lower state and the “S2” or higher state. The read voltage R3 is for use in distinction between the “S2” or lower state and the “S3” or higher state. The read voltage R4 is for use in distinction between the “S3” or lower state and the “S4” or higher state. The read voltage R5 is for use in distinction between the “S4” or lower state and the “S5” or higher state. The read voltage R6 is for use in distinction between the “S5” or lower state and the “S6” or higher state. The read voltage R7 is for use in distinction between the “S6” or lower state and the “S7” or higher state. A read pass voltage VREAD is set to a voltage higher than the highest state. The memory cell transistor MC to a gate of which the read pass voltage VREAD has been applied is turned on regardless of data to be stored therein.

In the read operation, the NAND flash memory 30 makes a determination using at least one read voltage as to which state the memory cell transistor MC is distributed in. For example, lower page data which is a set of lower-bit data is confirmed through the read operation using each of the read voltages R1 and R5. Middle page data which is a set of middle-bit data is confirmed through the read operation using each of the read voltages R2, R4, and R6. Upper page data which is a set of upper-page data is confirmed through the read operation using each of the read voltages R3 and R7. In a page read operation using the plurality of read voltages, arithmetic processing is performed as appropriate.

In a case of the memory cell transistor MC being a TLC (hereinafter referred to as a “TLC method”), the NAND flash memory 30 may allocate data differently. Furthermore, the NAND flash memory 30 may use a data storage method other than the TLC method and may use any data allocation. For example, one memory cell transistor MC may store 2-bit data or 4-or-more bit data. The operations described throughout this description may be executed regardless of the data storage method or the type of data allocation.

### 2.2 Write Operation

Next, the write operation will be described.

Hereinafter, the word line WL selected in the write operation will be referred to as a “word line WLsel”. The memory cell transistor MC coupled to the word line WLsel will be referred to as a “memory cell transistor MCsel”.

### 2.2.1 Outline of Write Operation

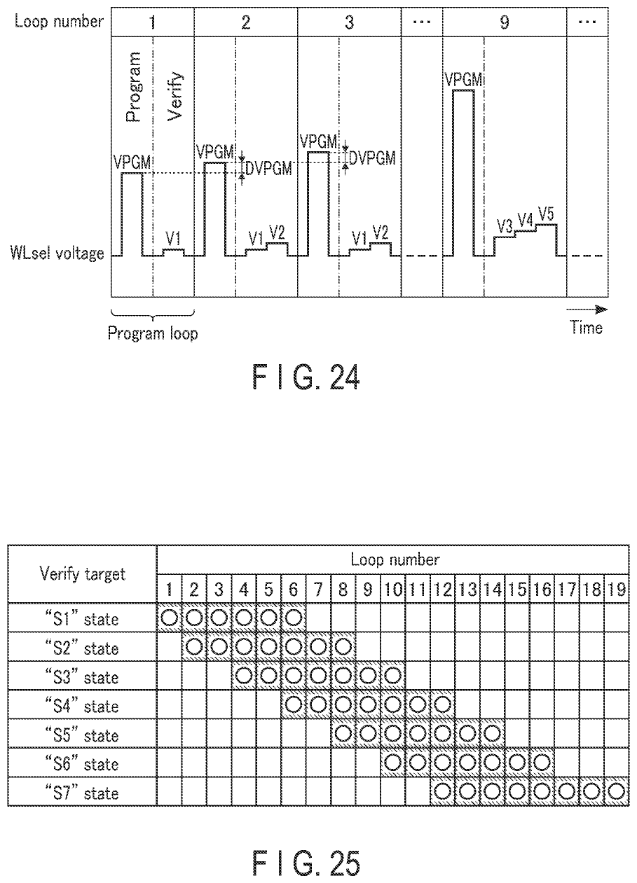

First, an outline of the write operation will be described with reference to FIG. 24. FIG. 24 is a timing chart showing an outline of the write operation. As shown in FIG. 24, the NAND flash memory 30 repeatedly performs a program loop in the write operation. FIG. 24 shows the number of times the program loop is performed during the write operation (hereinafter referred to as a “loop number”) and voltage changes in the word line WLsel (WLsel voltage). Each program loop includes a program operation (Program) and a program verify operation (Verify). That is, in the write operation, the program loop, including the program operation and the program verify operation, is repeatedly performed i times (where i is an integer equal to or greater than 2).

The program operation may cause a threshold voltage of the memory cell transistor MC to rise. In the program operation, the plurality of memory cell transistors MCsel coupled to the word line WLsel are set to a program-target or a program-inhabit based on write data stored in the associated sense amplifier unit SAU. Specifically, the memory cell transistor MCsel which has not reached a threshold voltage of a state which is a write target (hereinafter referred to as a “write state”) is set as the program-target. On the other hand, the memory cell transistor MCsel which has reached the threshold voltage of the write state is set as the program-inhibit.

In the program operation, a program voltage VPGM is applied to the word line WLsel. The program voltage VPGM is a voltage high enough to increase the threshold voltage of the memory cell transistor MCsel. The program voltage VPGM is stepped up in response to the program loop being repeated. That is, the program voltage VPGM may be increased in accordance with the number of times the program loop is performed. A step-up width DVPGM of the program voltage VPGM may be set to a given number. In the case where the program voltage VPGM is applied to the word line WLsel, the threshold voltage of the memory cell transistor MCsel coupled to the word line WLsel and to the bit line BL of the program-target rises. On the other hand, a rise in the threshold voltage of the memory cell transistor MCsel coupled to the word line WLsel and to the bit line BL of the program-inhibit is suppressed by, for example, a self-boost technique. Hereinafter, in the program operation, an operation of increasing a threshold voltage will be referred to as a “‘0’ write” or simply as a “write”. On the other hand, an operation of maintaining a threshold voltage will be referred to as a “‘1’ write” or simply as a “non-write”. The bit line corresponding to the “0” write will be referred to as “BL(‘0’)”, and the bit line corresponding to the “1” write will be referred to as “BL(‘1’)”. That is, the bit line BL(“0”) is bit line BL coupled to the memory cell transistor MC which is a write target. The bit line BL(“1”) is a bit line BL coupled to the memory cell transistor MC which is a non-write target. Upon completion of the program operation, the sequencer 35 performs the program verify operation.

The program verify operation is a read operation to check whether the threshold voltage of the memory cell transistor MCsel has reached the threshold voltage of the write state. The sequencer 35 performs the program verify operation on the memory cell transistor MCsel which is set to the program-target and also corresponds to the write state which is a verify target in the same program loop.

In the program verify operation, the sense amplifier unit SAU makes a determination based on a voltage of the bit line BL as to whether the threshold voltage of the memory cell transistor MCsel has exceeded the verify voltage applied to the word line WLsel. Each of the sense amplifier units SAU determines that the memory cell transistor MCsel whose threshold value is considered to have exceeded the verify voltage, that is, whose threshold value is considered to have reached the threshold voltage of the write state, is a “verify pass”. On the other hand, each of the sense amplifier units SAU determines that the memory cell transistor MCsel whose threshold value is considered to be the verify voltage or smaller, that is, whose threshold value is not considered to have reached the threshold voltage of the write state, is a “verify fail”. Each of the sense amplifier units SAU causes one of the latch circuits therein to store a verify result of the write state described above. Upon completion of the program verify operation, the sequencer 35 sets each memory cell transistor MCsel to the program-target or the program-inhibit based on the verify result in the current program loop, and then initiates the next program loop.

Meanwhile, the NAND flash memory 30 may execute the detection operation (“Detection”) as appropriate after each program loop. In the detection operation, the number of memory cell transistors MCsel that have passed the program verify operation is counted for each write state. The sequencer 35 makes a determination based on a count value for each write state as to whether write of the write state has been completed or not. During the repetition of the program loop, upon detection of a fact that the number of memory cell transistors MCsel, which has not yet passed the program verify operation of the “S1” to “S7” states, for example, has fallen below a predetermined number, the sequencer 35 terminates the write operation.

### 2.2.2 Specific Example of Program Loop

Next, a specific example of the program loop will be described with reference to FIG. 25. FIG. 25 is a table showing an example of setting of a program loop in the write operation. The table shown in FIG. 25 shows a relationship between a loop number and a write state of a verify target assigned to the loop concerned, and a white circle is entered in each portion to which the program verify operation is set.

As shown in FIG. 25, the type and the number of write states serving as the verify target may be changed in accordance with the progress of the program loop. In this example, the sequencer 35 executes the program loop nineteen times at most. Then, the sequencer 35 executes the program verify operation targeting at least one type of state for each of the nineteen program loops.

Specifically, the “S1” state is set to the verify target in the program loop performed for the first time to the sixth time. The “S2” state is set to the verify target in the program loop performed for the second time to the eighth time. The “S3” state is set to the verify target in the program loop performed for the fourth time to the tenth time. The “S4” state is set to the verify target in the program loop performed for the sixth time to the twelfth time. The “S5” state is set to the verify target in the program loop performed for the eighth time to the fourteenth time. The “S6” state is set to the verify target in the program loop performed for the tenth time to the sixteenth time. The “S7” state is set to the verify target in the program loop performed for the twelfth time to the nineteenth time.

Meanwhile, the number of times the NAND flash memory 30 can execute the program loop during one write operation may be any other number. Even in the case where write has not been completed for all the write states, the sequencer 35 may terminate the write operation in response to the program loop having been executed a predetermined number of times. The write state of the verify target associated with the loop number may be set differently. The sequencer 35 may omit, based on a result of the detection operation, the program operation and the program verify operation of the write state concerned in the program verify performed from the next time.

### 2.2.3 Voltages of Respective Interconnects During Program Operation

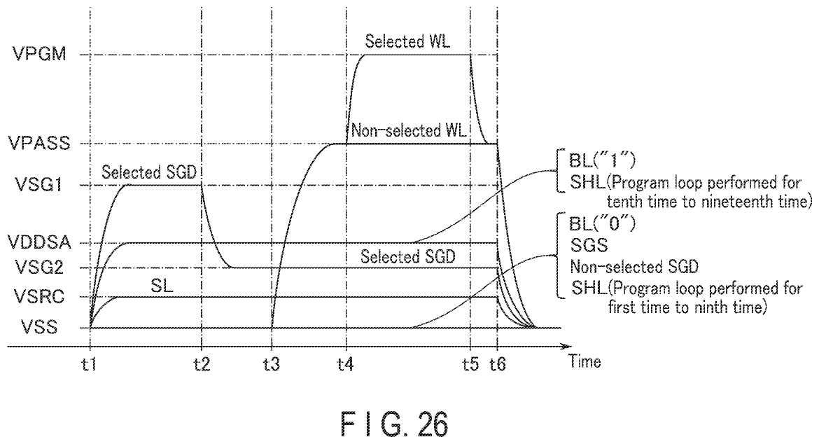

Voltages of respective interconnects during the program operation will be described with reference to FIG. 26. FIG. 26 is a timing chart showing an example of voltages of respective interconnects during the program operation. Hereinafter, a case in which the write operation is executed in the string unit SU0 of the block BLK0 will be described.

As shown in FIG. 26, the voltage VSRC is applied to the source line SL at time t1. The voltage VSRC is a voltage higher than the voltage VSS.

The row decoder RD0 corresponding to the selected block BLK0 applies the voltage VSG1 to the select gate line SGD0 (reference symbol “select SGD” in FIG. 26) corresponding to the selected string unit SU0, and applies the voltage VSS to the select gate lines SGD1 to SGD3 (reference symbol “non-selected SGD” in FIG. 26) corresponding to the non-selected string units SU1 to SU3. The voltage VSG1 is a voltage that turns on the select transistor ST1 regardless of a voltage of the corresponding bit line BL. This turns on the select transistor ST1 of each of the selected string units SU0 and turns off the select transistor ST1 of each of the non-selected string units SU1 to SU3.

Furthermore, the row decoder RD0 applies the voltage VSS to the select gate line SGS. This turns off the select transistor ST2 of the block BLK0.

The sense amplifier 43 applies the voltage VDDSA to the bit line BL(“1”), and applies the voltage VSS to the bit line BL(“0”). The voltage VDDSA is a voltage for use in the sense amplifier 43. The voltage VDDSA is a voltage higher than the voltage VSRC.

In the selected string unit SU0, voltage VDDSA is applied to a channel of the NAND string NS corresponding to the bit line BL(“1”), and the voltage VSS is applied to a channel of the NAND string NS corresponding to the bit line BL(“0”).

The bit line BL(“0”) which has passed the program verify operation in a program loop serves as the bit line BL(“1”) in a next program loop. Therefore, as the number of times the program loop is performed increases, the number of bit lines BL(“0”) decreases and the number of bit lines BL(“1”) increases in the selected string unit SU0. As the number of bit lines BL(“1”) increases, a time required for a voltage to rise from the voltage VSS to the voltage VDDSA in all of the bit lines BL(“1”) within the selected string unit SU0 becomes longer.

For this reason, in the present embodiment, since the number of bit lines BL(“1”) is comparatively small in the program loop performed for the first time to the j-th time (where j is an integer equal to or greater than 1 and equal to or smaller than i−1), the shield line driver 45 applies the voltage VSS to be applied to the bit line BL(“0”) to the shield line SHL within the plane region PLA, for example. As shown in FIG. 26, in the program loop performed for the first time to the ninth time, at time t1, the shield line driver 45 applies the voltage VSS to the shield line SHL within the plane region PLA, for example.

On the other hand, since the number of bit lines BL(“1”) is comparatively large in the program loop performed for the (j+1)-th time to the i-th time, the shield line driver 45 applies the voltage VDDSA to be applied to the bit line BL(“1”) to the shield line SHL within the plane region PLA, for example. As shown in FIG. 26, in the program loop performed for the tenth time to the nineteenth time, at the time t1, the shield line driver 45 applies the voltage VDDSA to the shield line SHL within the plane region PLA, for example.

In the case where the voltage VDDSA is applied to the shield line SHL, a potential of the bit line BL rises because of capacitance coupling between the shield line SHL and the bit line BL. Therefore, a rising time of the bit line BL(“1”) is shortened as compared to a case in which the voltage VSS is applied to the shield line SHL during the write operation. This shortens a time required for a voltage to rise from the voltage VSS to the voltage VDDSA in all of the bit lines BL(“1”) within the selected string unit SU0. As described above, the shield line SHL within the plane region PLA serves to assist voltage rise of the bit line BL(“1”).

Meanwhile, the voltage applied to the shield line SHL in the program loop performed for the first time to the ninth time is not necessarily the voltage VSS. The voltage applied to the shield line SHL in the program loop performed for the tenth time to the nineteenth time is not necessarily the voltage VDDSA. For example, it suffices that the voltage applied to the shield line SHL in the program loop performed for the first time to the ninth time is smaller than the voltage applied to the shield line SHL in the program loop performed for the tenth time to the nineteenth time. Furthermore, in FIG. 26, the voltage applied to the shield line SHL is divided into those applied in the program loop performed for the first time to the ninth time and those applied in the program loop performed for the tenth time to the nineteenth time: however, the voltage may be divided differently. For example, the voltage may be divided into those applied in the program loop performed for the first time to the eighth time and those applied in the program loop for the eighth time to the nineteenth time or those applied in the program loop performed for the first time to the tenth time and those applied in the program loop performed for the eleventh time to the nineteenth time.

At time t2, the row decoder RD0 applies a voltage VSG2 to the select gate line SGD0 of the selected string unit SU0. The voltage VSG2 is a voltage that turns the select transistor ST1 corresponding to the bit line BL(“1”) to a cutoff state, and turns the select transistor ST1 corresponding to the bit line BL(“0”) to the on state. Therefore, for example, a relationship between the voltage VDDSA and the voltages VSG1 and VSG2 is expressed as (VSG1−Vth)>VDDSA>(VSG2−Vth) (where the voltage Vth is a threshold voltage of the select transistor ST1). This turns a channel of the NAND string NS of the selected string unit SU0 coupled to the bit line BL(“1”) to a floating state.

At time t3, the row decoder RD0 applies the voltage VPASS to the word line WL. The voltage VPASS is a voltage that turns on the memory cell transistor MC regardless of the threshold voltage of the memory cell transistor MC.

At time t4, the row decoder RD0 applies the write voltage VPGM to the selected word line WL. The voltage VPGM is a voltage higher than the voltage VPASS.

In the NAND string NS corresponding to the bit line BL(“0”), the select transistor ST1 is in the on state. Therefore, a potential of a channel in the memory cell transistor MC is maintained at VSS. This increases a potential difference (VPGM-VSS) between the control gate and the channel, and as a result, electrons are injected into the charge storage layer, thereby causing the threshold voltage of the memory cell transistor MC to rise.

Furthermore, in the NAND string NS corresponding to the bit line BL(“1”), the select transistor ST1 is in the cutoff state. Therefore, a channel potential rises due to capacitance coupling with the selected word line WL. This results in the decreased potential difference between the control gate and the channel. As a result, few electrons are injected into the charge storage layer, so that the threshold voltage of the memory cell transistor MC is maintained.

At time t5, the row decoder RD0 applies the voltage VPASS to the selected word line WL.

At time t6, a recovery operation is performed, thereby terminating the program operation. The shield line driver 45 applies the voltage VSS to the shield line SHL within the plane region PLA.

### 2.3 Advantageous Effect of Present Embodiment

The second embodiment produces advantageous effects similar to those of the first embodiment.

The NAND flash memory 30 according to the present embodiment controls a voltage to be supplied to the shield line SHL within the plane region PLA during the write operation. Specifically, in the program loop performed for the first time to the ninth time, the shield line driver 45 applies the voltage VSS to the shield line SHL within the plane region PLA. In the program loop performed for the tenth time to the nineteenth time, the shield line driver 45 applies the voltage VDDSA to the shield line SHL within the plane region PLA. In the case where the voltage VDDSA is applied to the shield line SHL, a potential of the bit line BL rises owing to capacitance coupling between the shield line SHL and the bit line BL. Therefore, a rising time of the bit line BL(“1”) is shortened as compared to a case in which the voltage VSS is applied to the shield line SHL during the write operation. This can enhance the operation speed. Furthermore, a time required to charge the bit line BL(“1”) with an electric charge is shortened as compared to a case in which the voltage VSS is applied to the shield line SHL during the write operation. This realizes reduction in power consumption. Furthermore, in the case where a voltage applied to the shield line SHL is equal to a voltage applied to the bit line BL(“1”) adjacent to the aforementioned shield line SHL, the influence of noise is less for each compared to a case in which these voltages differ. This realizes reduction in influence of noise.

### 2.4 First Modification

The NAND flash memory 30 according to a first modification of the second embodiment is different from that of the second embodiment in terms of the method of controlling a voltage supplied to the shield line SHL within the plane region PLA. Hereinafter, with respect to the NAND flash memory 30 according to the first modification of the second embodiment, the difference from the second embodiment will be described.

### 2.4.1 Voltages of Respective Interconnects During Program Operation

In the present modification, a voltage (hereinafter referred to as a “shield line voltage VSHL”) applied to the shield line SHL within the plane region PLA by the shield line driver 45 is stepped up in accordance with the program loop being repeated, for example. That is, the shield line voltage VSHL may be increased in accordance with the number of times the program loop is executed. A step-up width DVSHL (hereinafter also referred to as a “difference voltage DVSHL”) of the shield line voltage VSHL may be set to a given number.

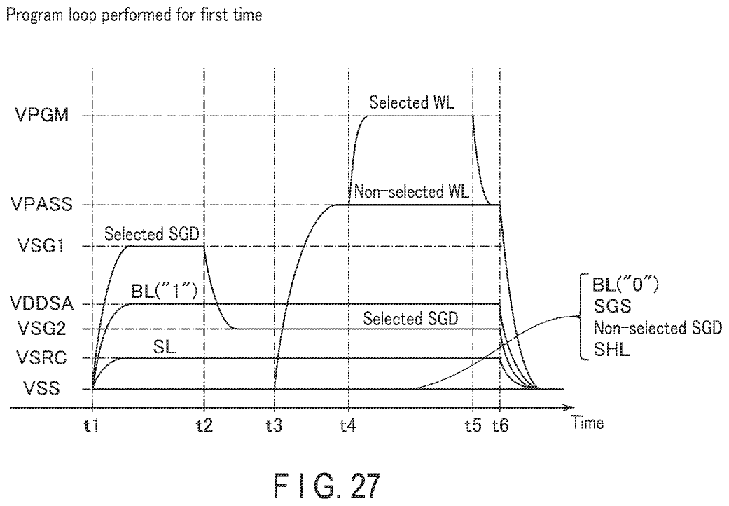

Voltages of respective interconnects during the program operation will be described with reference to FIG. 27 to FIG. 30. FIG. 27 to FIG. 30 are each a timing chart showing an example of voltages of respective interconnects during the program operation. Hereinafter, a case in which the write operation is executed in the string unit SU0 of the block BLK0 will be described. In FIG. 27 to FIG. 30, voltages of interconnects other than the shield line SHL from the time t1 to the time t6 are substantially identical to those shown in FIG. 26 described in the second embodiment.

For example, in the program loop performed for the first time, the shield line driver 45 applies the voltage VSS, which is to be applied to the bit line BL(“0”), to the shield line SHL within the plane region PLA. In the program loop performed for the k-th time (where k is an integer equal to or greater than 2), the shield line driver 45 applies, to the shield line SHL within the plane region PLA, a voltage obtained by adding the difference voltage DVSHL to a voltage that is applied to the shield line SHL within the plane region PLA during the program loop performed for the (k−1)-th time.

As shown in FIG. 27, in the program loop performed for the first time, the shield line driver 45 applies the voltage VSS to the shield line SHL within the plane region PLA at the time t1, for example. The rest of the operation after the time t1 is similar to that shown in FIG. 26 described in the second embodiment.

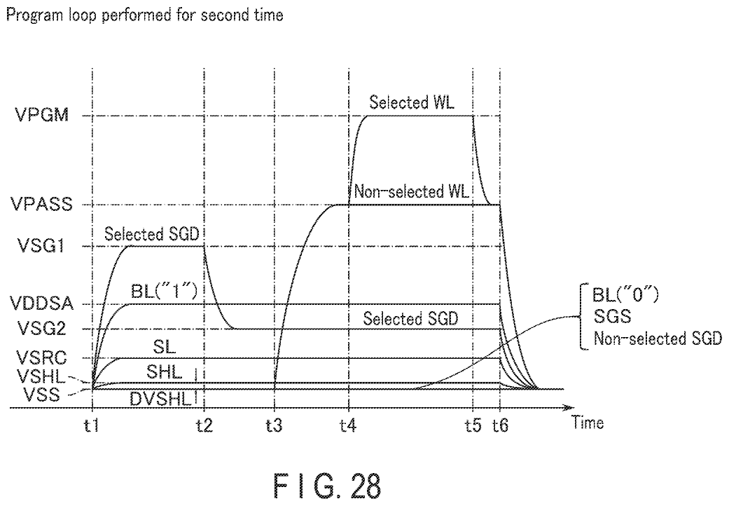

As shown in FIG. 28, in the program loop performed for the second time, at the time t1, the shield line driver 45 applies, as the shield line voltage VSHL, a voltage obtained by adding the voltage DVSHL to the voltage VSS to the shield line SHL within the plane region PLA, for example. The rest of the operation after the time t1 is similar to that shown in FIG. 26 described in the second embodiment.

As in the program loop performed for the second time, in the program loop performed for the third time to the seventeenth time, at the time t1, the stepped-up shield line voltage VSHL is applied to the shield line SHL within the plane region PLA. The rest of the operation after the time t1 is similar to that shown in FIG. 26 described in the second embodiment.

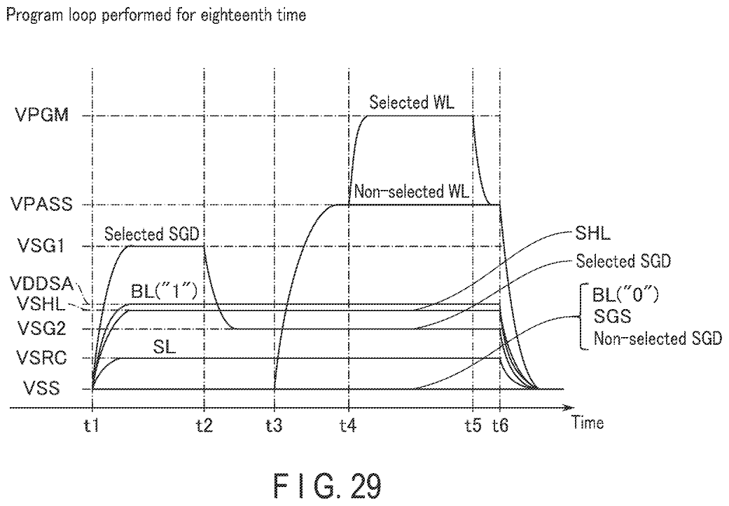

As shown in FIG. 29, in the program loop performed for the eighteenth time, at the time t1, the shield line driver 45 applies, as the shield line voltage VSHL, for example, a voltage stepped up from the shield line voltage VSHL in the program loop performed for the seventeenth time to the shield line SHL within the plane region PLA. The rest of the operation after the time t1 is similar to that shown in FIG. 26 described in the second embodiment.

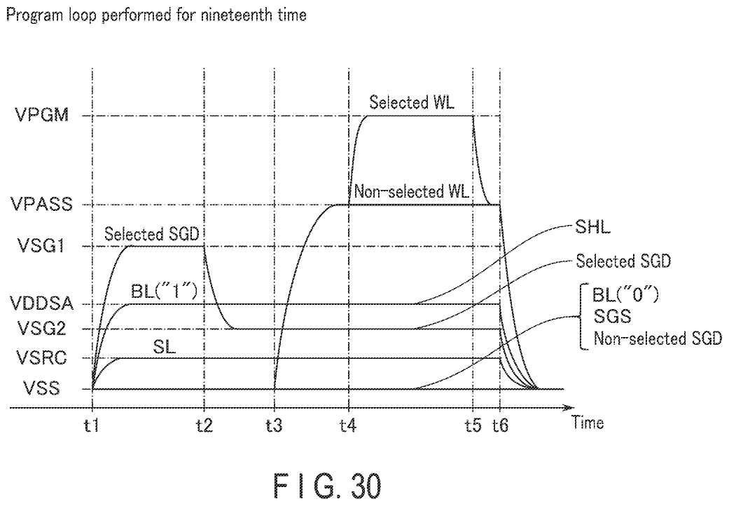

As shown in FIG. 30, in the program loop performed for the nineteenth time, at the time t1, the shield line driver 45 applies, as the shield line voltage VSHL, for example, the voltage VDDSA stepped up from the shield line voltage VSHL in the program loop performed for the eighteenth time to the shield line SHL within the plane region PLA. The rest of the operation after the time t1 is similar to that shown in FIG. 26 described in the second embodiment.

### 2.4.2 Advantageous Effect of Present Modification

The present modification produces advantageous effects similar to those of the first embodiment.

Furthermore, the NAND flash memory 30 according to the present modification steps up a voltage that is applied to the shield line SHL within the plane region PLA during the write operation. In the case where the stepped-up voltage is applied to the shield line SHL, a potential of the bit line BL rises because of capacitance coupling between the shield line SHL and the bit line BL. Therefore, a rising time of the bit line BL(“1”) is shortened as compared to a case in which the voltage VSS is applied to the shield line SHL during the write operation. This can enhance the operation speed. Furthermore, a time required to charge the bit line BL(“1”) with an electric charge is shortened as compared to a case in which the voltage VSS is applied to the shield line SHL during the write operation. This realizes reduction in power consumption.

### 2.5 Second Modification

The NAND flash memory 30 according to a second modification of the second embodiment is different from that of the second embodiment in terms of the layout of the shield line SHL within the array chip 100. Furthermore, the NAND flash memory 30 according to the second modification of the second embodiment is different from that of the second embodiment in terms of the method of controlling a voltage supplied to the shield line SHL within the plane region PLA. Hereinafter, with respect to the NAND flash memory 30 according to the second modification of the second embodiment, the difference from the second embodiment will be described.

### 2.5.1 Layout of Shield Line

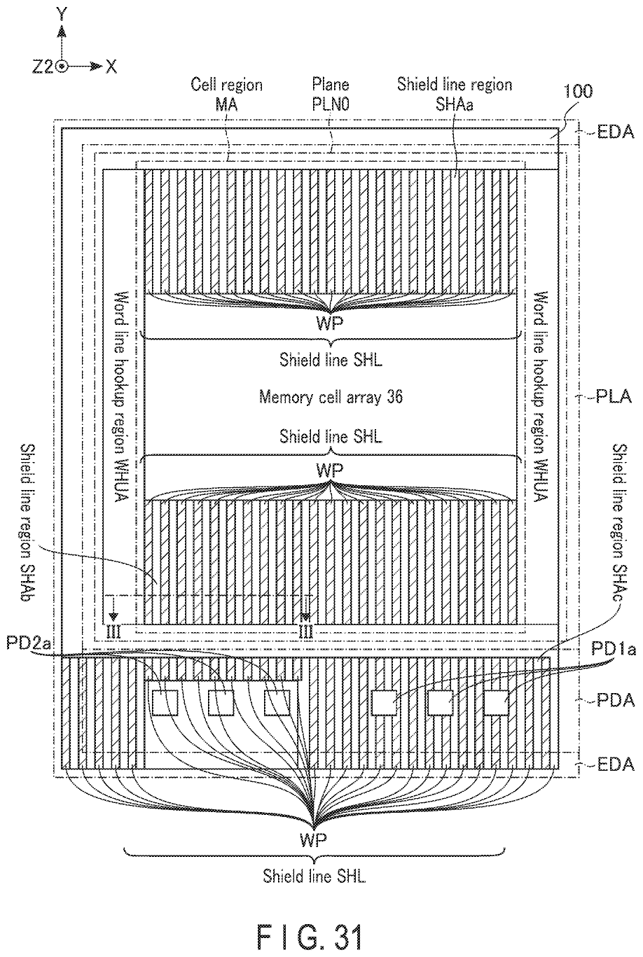

FIG. 31 is a planar view showing an example of a planar layout of the shield lines SHL within the array chip 100. FIG. 31 shows the plane PLN0, and the shield line region SHAc and pads PD1a and PD2a which correspond to the plane PLN0.

The shield line regions SHAa, SHAb, and SHAc are each provided with the shield line SHL. The shield line SHL includes, for example, the plurality of interconnect portions WP. The plurality of interconnect portions WP are each formed into, for example, a line shape extending in the Y direction and are spaced apart from each other in the X direction. Meanwhile, in the shield line region SHAc, the shield line SHL is provided in such a manner as to avoid overlap with the plurality of pads PD2a in the Z direction, for example.

In the shield line regions SHAa, SHAb, and SHAc, the shield line SHL is provided in a layer between the bonding surface and the bit line BL as in FIG. 17 described in the first embodiment. The shield line SHL within the shield line region SHAa is spaced apart from the shield line SHL within the shield line region SHAb in the Y direction. The shield line SHL within the shield line region SHAb is spaced apart from the shield line SHL within the shield line region SHAc in the Y direction.

### 2.5.2 Cross-Sectional Structure of NAND Flash Memory

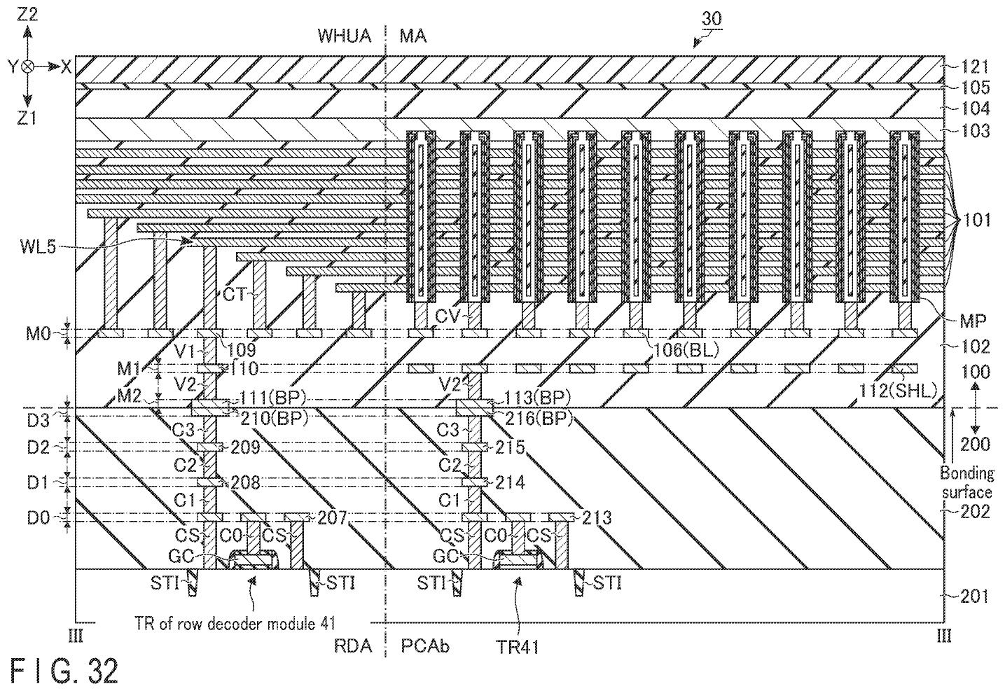

FIG. 32 is a cross-sectional view taken along the line III to III of FIG. 31 and showing an example of a cross-sectional structure of the NAND flash memory 30.

As shown in FIG. 32, an upper cross-sectional structure of the interconnect layer 106 in the cell region MA of the array chip 100 is similar to an upper cross-sectional structure of the interconnect layer 106 in the cell region MA shown in FIG. 18 described in the first embodiment. A cross-sectional structure of the word line hookup region WHUA in the array chip 100 is similar to a cross-sectional structure of the word line hookup region WHUA shown in FIG. 18 described in the first embodiment.

In the cell region MA, the interconnect layer 112 (the interconnect portion WP of the shield line SHL) is arranged in a position facing the interconnect layer 106 in the Z direction. In other words, the interconnect layer 112 overlaps the interconnect layer 106 in the Z direction. The interconnect layer 112 is electrically coupled to the bonding pad 113 with the contact plug V2 intervening therebetween.

As shown in FIG. 32, a cross-sectional structure of the peripheral circuit region PCAb of the circuit chip 200 is similar to a cross-sectional structure of the peripheral circuit region PCAb shown in FIG. 18 described in the first embodiment. A cross-sectional structure of the row decoder region RDA of the circuit chip 200 is similar to a cross-sectional structure of the row decoder region RDA shown in FIG. 18 described in the first embodiment.

With the configuration described above, a voltage is applied by the shield line driver 45 to the interconnect layer 112 provided in the cell region MA (plane region PLA). That is, voltages are applied from the separate transistors TR41 within the shield line driver 45 to the separate interconnect layers 112. In other words, the shield line driver 45 is coupled to the plurality of interconnect portions WP of the shield line SHL within the plane region PLA, and applies a voltage to the plurality of interconnect portions WP separately.

### 2.5.3 Voltages of Respective Interconnects During Program Operation

In the present modification, the shield line driver 45 applies a voltage separately to the plurality of interconnect portions WP included in the shield line SHL within the plane region PLA. A voltage applied by the shield line driver 45 to the interconnect portions WP of the shield line within the plane region PLA is a voltage applied to the bit lines BL respectively facing the interconnect portions WP in the Z direction. Hereinafter, the interconnect portion WP of the shield line SHL in a position facing the bit line BL(“0”) in the Z direction will be referred to as “SHL(‘0’)”, and the interconnect portion WP of the shield line SHL in a position facing the bit line BL(“1”) in the Z direction will be referred to as “SHL(‘1’)”.

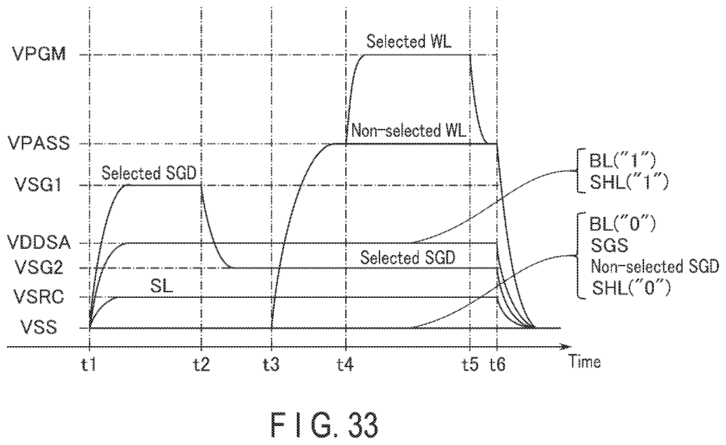

Voltages of respective interconnects during the program operation will be described with reference to FIG. 33. FIG. 33 is a timing chart showing an example of voltages of respective interconnects during the program operation. Hereinafter, a case in which the write operation is executed in the string unit SU0 of the block BLK0 will be described. In FIG. 33, voltages of interconnects other than the shield line SHL from the time t1 to the time t6 are substantially identical to those shown in FIG. 26 described in the second embodiment.

At the time t1, the shield line driver 45 applies the voltage VSS, which is to be applied to the bit line BL(“0”), to the shield line SHL (“0”) within the plane region PLA, for example. The shield line driver 45 applies the voltage VDDSA, which is to be applied to the bit line BL(“1”), to the shield line SHL (“1”) within the plane region PLA, for example. At the time t6, the shield line driver 45 applies the voltage VSS to the shield line SHL within the plane region PLA.

### 2.5.4 Advantageous Effect of Present Modification

The present modification produces advantageous effects similar to those of the first embodiment and the second embodiment.

Furthermore, the NAND flash memory 30 according to the present modification applies a voltage separately to the plurality of interconnect portions WP included in the shield line SHL arranged in the shield line region within the plane region PLA. Therefore, voltage rise of the bit line BL can be assisted more appropriately in accordance with a voltage applied to the bit line BL.

### 2.6 Third Modification

The NAND flash memory 30 according to the third modification of the second embodiment differs from that of the second embodiment in terms of controlling a voltage to be supplied to the shield line SHL within the plane region PLA during the read operation. Hereinafter, with respect to the NAND flash memory 30 according to the third modification of the second embodiment, the difference from the second embodiment will be described.

### 2.6.1 Voltages of Respective Interconnects During Read Operation

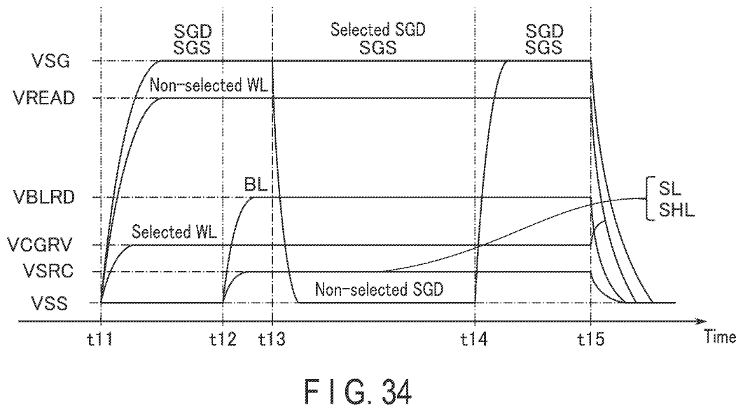

Voltages of respective interconnects during the read operation will be described with reference to FIG. 34. FIG. 34 is a timing chart showing an example of voltages of respective interconnects during the read operation. Meanwhile, the program verify operation and the erase verify operation to be described later exhibit similar waveforms, and the read voltage VCGRV of the selected word line WL varies depending on the verify level. Hereinafter, a case in which the read operation is executed in the string unit SU0 of the block BLK0 will be described.

As shown in FIG. 34, at time t11, the row decoder RD0 applies the voltage VSG to select gate lines SGD0 to SGD3 and SGS in the selected block BLK0. The voltage VSG is a voltage that turns on the select transistor ST1 regardless of a voltage of the corresponding bit line BL. Furthermore, the row decoder RD0 applies the voltage VCGRV to the selected word line WL, and applies the voltage VREAD to the non-selected word line WL. The voltage VCGRV is a read voltage according to a threshold voltage level of the read data. The voltage VREAD is a voltage that turns on the memory cell transistor MC regardless of the threshold voltage. A relationship between the voltage VCGRV and the voltage VREAD is expressed as VCGRV<VREAD. By this, unnecessary electric charge in a channel of the NAND string NS is discharged in the non-selected string units SU1 to SU3. FIG. 34 shows that the voltage VSG is higher than the voltage VREAD; however, the voltage VSG may be lower than the voltage VREAD.

At time t12, the sense amplifier 43 applies the voltage VBLRD to the bit line BL. The voltage VBLRD is a voltage that is applied to the bit line BL during the read operation. Furthermore, the voltage VSRC is applied to the source line SL. A relationship between the voltage VBLRD and the voltage VSRC is expressed as VBLRD>VSRC (>VSS).

It takes comparatively much time for a voltage to rise from the voltage VSS to the voltage VBLRD in all of the bit lines BL within the selected string unit SU0. In view of this, in the present modification, the shield line driver 45 applies a voltage higher than the voltage VSS to the shield line SHL within the plane region PLA at the time t12. In the case where the voltage VBLRD is applied to the shield line SHL, a potential of the bit line BL may be increased excessively by capacitance coupling between the shield line SHL and the bit line BL. For this reason, the shield line driver 45 applies the voltage VSRC, which is to be applied to the source line SL, to the shield line SHL within the plane region PLA, for example. This shortens a time required for a voltage to rise from the voltage VSS to the voltage VBLRD in all of the bit lines BL within the selected string unit SU0. As described above, the shield line SHL within the plane region PLA serves to assist voltage rise of the bit line BL.

At time t13, the row decoder RD0 continuously applies the voltage VSG to the select gate line SGD (select SGD) corresponding to the selected string unit SU0 and the select gate line SGS, and applies, for example, the voltage VSS to the select gate lines SGD (non-selected SGD) corresponding to the non-selected string units SU1 to SU3. This turns the select transistors ST1 corresponding to the non-selected string units SU1 to SU3 to the cutoff state. In this state, the sense amplifier 43 reads data during a period from the time t13 to time t14.

At the time t14, the row decoder RD0 applies the voltage VSG to the select gate line SGD corresponding to the non-selected string units SU1 to SU3.

At time t15, the recovery operation is performed, thereby terminating the read operation. More specifically, the row decoder RD0 applies the voltage VSS to the select gate lines SGD and SGS and the word line WL. This equalizes the selected word line WL and the non-selected word line WL. Therefore, the voltage of the selected word line WL increases slightly and then drops down to the voltage VSS. The shield line driver 45 applies the voltage VSS to the shield line SHL within the plane region PLA.

### 2.6.2 Advantageous Effect of Present Modification

The present modification produces advantageous effects similar to those of the first embodiment.

Furthermore, the NAND flash memory 30 according to the present modification applies the voltage VSRC, which is to be applied to the source line SL, to the shield line SHL within the plane region PLA during the read operation. In the case where the voltage VSRC is applied to the shield line SHL, a potential of the bit line BL rises due to capacitance coupling between the shield line SHL and the bit line BL. Therefore, a rising time of the bit line BL is shortened as compared to a case in which the voltage VSS is applied to the shield line SHL during the read operation. This can enhance the operation speed. Furthermore, a time required to charge the bit line BL with an electric charge is shortened as compared to a case in which the voltage VSS is applied to the shield line SHL during the read operation. This realizes reduction in power consumption.

### 2.7 Fourth Modification

The NAND flash memory 30 according to a fourth modification of the second embodiment is different from that of the third modification of the second embodiment in terms of the method of controlling a voltage supplied to the shield line SHL within the plane region PLA. Hereinafter, with respect to the NAND flash memory 30 according to the fourth modification of the second embodiment, the difference from the third modification of the second embodiment will be described.

2.7.1 Voltages of Respective Interconnects during Read Operation

In the read operation of the current sensing type, a voltage of a bit line BL is basically set constant; however, a slight difference in voltage level is caused depending on whether the memory cell MC to which the bit line BL is coupled is turned on or off.

For example, in the case where a voltage of the selected word line WL is comparatively high, the number of memory cells MC which are turned on (hereinafter also referred to as “on-cells”) becomes greater than the number of memory cells MC which are turned off (hereinafter also referred to as “off-cells”. Thus, this case assumes that an average voltage of bit lines BL relatively decreases. On the other hand, in the case where a voltage of the selected word line WL is comparatively low, the number of off-cells is greater than the number of on-cells. Thus, this case assumes that an average voltage of the bit lines BL relatively increases. In view of this, in order to appropriately assist voltage rise of the bit line BL, which is variable in the current sensing type, the present modification changes a voltage to be applied to the shield line SHL in accordance with a voltage of the select word line WL (the word line coupled to the memory cell MC serving as a read target). That is, a voltage based on a voltage to be applied to the selected word line WL is applied to the shield line SHL. For example, a voltage to be applied to the shield line SHL is set lower as a voltage of selected word line WL is higher, and a voltage to be applied to the shield line SHL is set higher as a voltage of selected word line WL is lower.

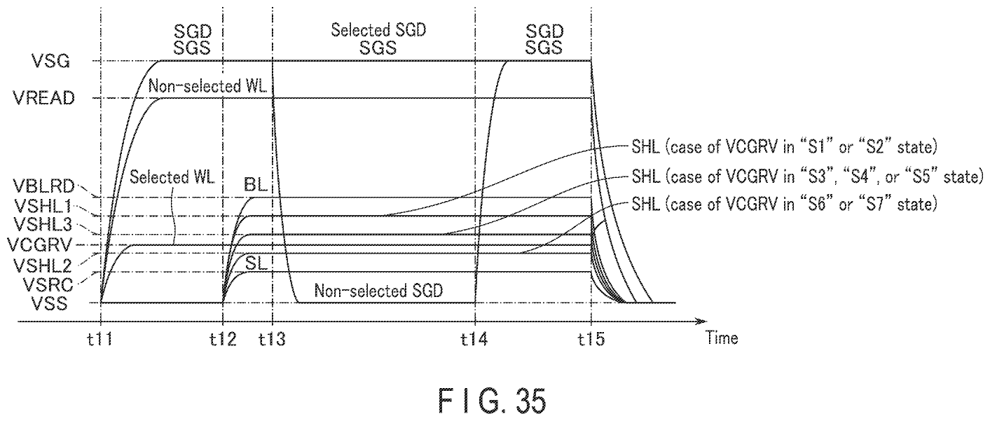

Voltages of respective interconnects during the read operation will be described with reference to FIG. 35. FIG. 35 is a timing chart showing an example of voltages of respective interconnects during the read operation. Hereinafter, a case in which the read operation is executed in the string unit SU0 of the block BLK0 will be described. In FIG. 35, voltages of interconnects other than the shield line SHL from the time t11 to the time t15 are substantially identical to those shown in FIG. 34 described in the third modification of the second embodiment.

In the case where the voltage VCGRV applied to the selected word line is a voltage in one of the “S1” and “S2” states shown in FIG. 23, at the time t12, the shield line driver 45 applies a comparatively high voltage ranging between the voltage VSRC and the voltage VBLRD (hereinafter referred to as a “first shield line voltage VSHL1”) to the shield line SHL within the plane region PLA, for example. In the case where the voltage VCGRV applied to the selected word line is a voltage in one of the “S6” and “S7” states shown in FIG. 23, at the time t12, the shield line driver 45 applies a comparatively low voltage ranging between the voltage VSRC and the voltage VBLRD (hereinafter referred to as a “second shield line voltage VSHL2”) to the shield line SHL within the plane region PLA, for example. Furthermore, in the case where the voltage VCGRV applied to the selected word line is a voltage in one of the “S3” to “S5” states shown in FIG. 23, at the time t12, the shield line driver 45 applies a voltage ranging between the first shield line voltage VSHL1 and the second shield line voltage VSHL2 (hereinafter referred to as a “third shield line voltage VSHL3”) to the shield line SHL within the plane region PLA, for example. That is, the voltage VSHL to be applied to the shield line SHL is a voltage ranging between the voltage VSRC to be applied to the source line SL and the voltage VBLRD to be applied to the bit line. At time t15, the shield line driver 45 applies the voltage VSS to the shield line SHL within the plane region PLA.

Meanwhile, FIG. 35 shows that voltages applied to the shield line SHL are classified into a voltage in a case where the voltages VCGRV is in the “S1” and “S2” states, a voltage in a case where the voltages VCGRV is in the “S3” to “S5” states, and a voltage in a case where the voltages VCGRV is in the “S6” and “S7” states. However, voltages applied to the shield line SHL may be classified differently. For example, the aforementioned voltages may be classified into a voltage in a case where the voltages VCGRV is in the “$1” to “S4” states and a voltage in a case where the voltages VCGRV is in the “S5” to “S7” states.

### 2.7.2 Advantageous Effect of Present Modification

The present modification produces advantageous effects similar to those of the first embodiment.

Furthermore, as described above, in the case where a voltage of the selected word line WL is comparatively high, it is assumed that an average voltage of the bit lines BL relatively decreases. In the case where a voltage of the selected word line WL is comparatively low, it is assumed that an average voltage of the bit lines BL relatively increases. In view of this, the NAND flash memory 30 according to the present modification applies a voltage according to a voltage of the selected word line WL to the shield line SHL within the plane region PLA during the read operation. In the case where the voltage according to the voltage of the selected word line WL is applied to the shield line SHL, a potential of the bit line BL rises due to capacitance coupling between the shield line SHL and the bit line BL. Therefore, a rising time of the bit line BL is shortened as compared to a case in which the voltage VSS is applied to the shield line SHL during the read operation. This can enhance the operation speed.

Furthermore, a time required to charge the bit line BL with an electric charge is shortened as compared to a case in which the voltage VSS is applied to the shield line SHL during the read operation. This realizes reduction in power consumption. Furthermore, since the voltage according to selected word line WL is applied to the shield line SHL, the shield line SHL can more appropriately assist voltage rise of the bit line BL, which is variable in the current sensing type.

### 2.8 Fifth Modification

The NAND flash memory 30 according to a fifth modification of the second embodiment differs from that of the second embodiment in terms of controlling a voltage to be supplied to the shield line SHL within the plane region PLA during the erase operation. Hereinafter, with respect to the NAND flash memory 30 according to the fifth modification of the second embodiment, the difference from the second embodiment will be described.

### 2.8.1 Overview of Erase Operation

An overview of the erase operation will be described. The erase operation includes an erase voltage application operation and an erase verify operation. The erase voltage application operation is an operation in which a threshold voltage of the memory cell transistor MC serving as an erase target is decreased by applying the voltage VERA to the memory cell transistor MC concerned. The voltage VERA is a voltage higher than, for example, a voltage for use in the read operation. The voltage VERA is applied to the memory cell transistor MC via interconnects (for example, the source line SL and the bit line BL). The erase verify operation is an operation in which a determination is made as to whether a threshold voltage of the memory cell transistor MC is lower or not than a target voltage. The erase verify operation is executed after the erase voltage application operation. Hereinafter, a case in which a threshold value of a memory cell MC transistor is smaller than a target voltage will be described as a memory cell transistor that has “passed the erase verify operation”. On the other hand, a case in which the threshold value of the memory cell transistor MC is equal to or greater than the target voltage will be described as a memory cell transistor MC that has “failed the erase verify operation”. Generally, the erase voltage application operation is executed in units of blocks BLK. The erase verify operation is executed in units of string units SU.

The memory controller 10 may give orders of the erase voltage application operation and the erase verify operation separately to the NAND flash memory 30. For example, another operation such as the write operation or read operation may be executed between the erase voltage application operation and the erase verify operation. Furthermore, for example, a block BLK selected during the erase voltage application operation may be different from a block BLK (string unit SU) selected during the erase verify operation.

During the erase operation, a combination of the erase voltage application operation and the erase verify operation (hereinafter referred to as an “erase loop”) is repeatedly executed until a threshold voltage of the memory cell transistor MC falls below the target voltage. Every time the erase loop is repeated, a set value of the voltage VERA in the erase voltage application operation is stepped up. For example, a set value of the voltage VERA is stepped up by the voltage DVERA. As described above, the stress by the erase operation can be reduced by gradually increasing the voltage VERA up to the final set value as compared to a case in which the voltage VERA is increased up to the final set value all in one go. Meanwhile, in the erase loop, the erase verify operation may be omitted.

### 2.8.2 Voltages of Respective Interconnects During Erase Voltage Application Operation

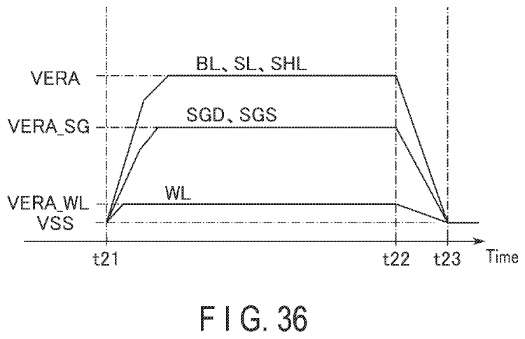

Voltages of respective interconnects during the erase voltage application operation will be described with reference to FIG. 36. FIG. 36 is a timing chart showing an example of voltages of respective interconnects during the erase voltage application operation. Hereinafter, a case in which the erase voltage application operation is executed in the block BLK0 will be described.

At time t21, the row decoder RD0 applies a voltage VERA SG to the select gate lines SGD and SGS and applies a voltage VERA WL to the word line WL. The voltage VERA SG is higher than the voltage VSS and is lower than the voltage VCC. The voltage VERA WL is higher than the voltage VSS and is lower than the voltage VERA SG. By the application of the voltage VERA SG, the voltage of each of the select gate lines SGD and SGS increases. By the application of the voltage VERA WL, the voltage of the word line WL increases. The sense amplifier 43 applies the voltage VERA to the bit line BL (the bit line BL coupled to the memory cell MC which is an erase target). The voltage VERA is a voltage higher than the voltage VCC. The voltage VERA is applied to the source line SL. By the application of the voltage VERA, the voltage of each of the bit line BL and the source line SL increases.

It takes comparatively much time for a voltage to rise from the voltage VSS to the voltage VERA in all of the bit lines BL within the selected block BLK0. In view of this, in the present modification, at the time t21, the shield line driver 45 applies the voltage VERA to be applied to the bit line BL to the shield line SHL within the plane region PLA. In the case where the voltage VERA is applied to the shield line SHL, a potential of the bit line BL rises due to capacitance coupling between the shield line SHL and the bit line BL. Therefore, a rising time of the bit line BL is shortened as compared to a case in which the voltage VSS is applied to the shield line SHL during the erase voltage application operation. This shortens a time required for a voltage to rise from the voltage VSS to the voltage VERA in all of the bit lines BL within the selected block BLK0. As described above, the shield line SHL within the plane region PLA serves to assist voltage rise of the bit line BL.

The threshold voltage of the memory cell MC decreases in the case where the voltage of each of the bit lines BL and the source line SL rises up to the voltage VERA, the voltage of each of the select gate lines SGD and SGS rises up to the voltage VERA SG, and the voltage of the word line WL rises up to the voltage VERA WL.

At time t22, the recovery operation is performed. Specifically, the row decoder RD0 applies the voltage VSS to the select gate lines SGD and SGS and the word line WL. The sense amplifier 43 applies the voltage VSS to the bit line BL. Furthermore, the voltage VSS is applied to the source line SL. The shield line driver 45 applies the voltage VSS to the shield line SHL within the plane region PLA.

At time t23, voltages of the bit line BL, the source line SL, the select gate lines SGD and SGS, and the word line WL become the voltage VSS. The erase voltage application operation is thus terminated.

### 2.8.3 Advantageous Effect of Present Modification

The present modification produces advantageous effects similar to those of the first embodiment.

Furthermore, the NAND flash memory 30 according to the present modification applies the voltage VERA, which is to be applied to the bit line SL, to the shield line SHL within the plane region PLA during the erase voltage application operation. In the case where the voltage VERA is applied to the shield line SHL, a potential of the bit line BL rises due to capacitance coupling between the shield line SHL and the bit line BL. Therefore, a rising time of the bit line BL is shortened as compared to a case in which the voltage VSS is applied to the shield line SHL during the erase voltage application operation. This can enhance the operation speed. Furthermore, a time required to charge the bit line BL with an electric charge is shortened as compared to a case in which the voltage VSS is applied to the shield line SHL during the erase voltage application operation. This realizes reduction in power consumption. Furthermore, in the case where a voltage applied to the shield line SHL is equal to a voltage applied to the bit line BL facing the aforementioned shield line SHL, the influence of noise is less for each compared to a case in which these voltages differ. This realizes reduction in the influence of noise.

### 3. Third Embodiment

The NAND flash memory 30 according to the third embodiment is different from that of the first embodiment in terms of the layout of the shield line SHL within the array chip 100. Hereinafter, with respect to the NAND flash memory 30 according to the third embodiment, the difference from the first embodiment will be described.

### 3.1 Layout of Shield Line

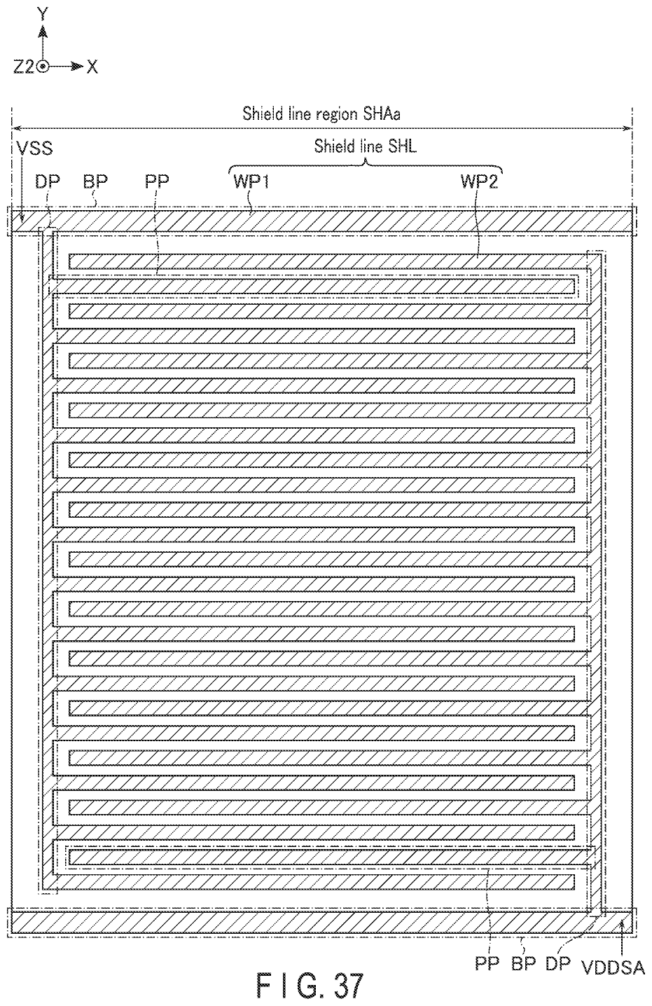

FIG. 37 is a planar view showing an example of a planar layout of the shield lines SHL within the array chip 100. FIG. 31 shows the shield line region SHAa within the plane PLN0.

As shown in FIG. 37, the shield line region SHAa is provided with the shield line SHL. The shield line SHL includes, for example, a first interconnect portion WP1 and a second interconnect portion WP2. Each of the first interconnect portion WP1 and the second interconnect portion WP2 includes, for example, a base portion BP, a hookup portion DP, and a plurality of projecting portions PP.

The base portion BP is arranged at the end portion in the Y direction and is formed into a line shape extending in the X direction. That is, the base portion BP of the first interconnect portion WP1 and the base portion BP of the second interconnect portion WP2 are respectively arranged in the both ends in the Y direction of the shield line region SHAa. A voltage is applied by the shield line driver 45 to each of the base portions BP. For example, the voltage VSS is applied to the base portion BP of the first interconnect portion WP1. The voltage VDDSA is applied to the base portion BP of the second interconnect portion WP2.

The hookup portion DP is, for example, coupled to a part of each base portion BP, and is formed into a line shape extending in the Y direction. Meanwhile, the hookup portion DP of the first interconnect portion WP1 is spaced apart from the base portion BP of the second interconnect portion WP2 in the Y direction. The hookup portion DP of the second interconnect portion WP2 is spaced apart from the base portion BP of the first interconnect portion WP1 in the Y direction.

The plurality of projecting portions PP are, for example, coupled to a part of each hookup portion DP, formed into a line shape extending in the X direction, and spaced apart from each other in the Y direction. Meanwhile, the plurality of projecting portions PP of the first interconnect portion WP1 are spaced apart from the hookup portion DP of the second interconnect portion WP2 in the X direction. The plurality of projecting portions PP of the second interconnect portion WP2 are spaced apart from the hookup portion DP of the first interconnect portion WP1 in the X direction. Each of the projecting portions PP of the first interconnect portion WP1 and each of the projecting portions PP of the second interconnect portion WP2 are alternately arranged and are apart from each other in the Y direction. The projecting portion PP coupled to the end portion in the Y direction of the hookup portion DP of the first interconnect portion WP1 is spaced apart from the base portion BP of the second interconnect portion WP2 in the Y direction. The projecting portion PP coupled to the end portion in the Y direction of the hookup portion DP of the second interconnect portion WP2 is spaced apart from the base portion BP of the first interconnect portion WP1 in the Y direction.

As in the shield line region SHAa, the shield line SHL including the first interconnect portion WP1 and the second interconnect portion WP2 is arranged in the shield line region SHAb within the plane PLN0 and the shield line region SHAc corresponding to the plane PLN0. Meanwhile, in the shield line region SHAc, the shield line SHL is provided in such a manner as to avoid overlap with the plurality of pads PD2a in the Z direction, for example. In the shield line region SHAc, a voltage is supplied from the pad PD1 to the base portion BP of each of the first interconnect portion WP1 and the second interconnect portion WP2 of the shield line SHL. For example, the voltage VSS is supplied to the base portion BP of the first interconnect portion WP1. The voltage VCC or VCCQ/VCCQL is supplied to the base portion BP of the second interconnect portion WP2.

In the shield line regions SHAa, SHAb, and SHAc, the shield line SHL is provided in a layer between the bonding surface and the bit line BL as in FIG. 17 described in the first embodiment. The shield line SHL within the shield line region SHAa is spaced apart from the shield line SHL within the shield line region SHAb in the Y direction. The shield line SHL within the shield line region SHAb is spaced apart from the shield line SHL within the shield line region SHAc in the Y direction.

In the shield line regions SHAa, SHAb, and SHAc, the first interconnect portion WP1 and the second interconnect portion WP2 included in the shield line SHL may have a configuration described hereinafter. For example, the base portion BP may be arranged in the end portion in the X direction and be formed into a line shape extending in the Y direction. The hookup portion DP may be coupled to a part of the base portion BP and be formed into a line shape extending in the X direction. The plurality of projecting portions PP may be, for example, coupled to a part of each hookup portion DP, be formed into a line shape extending in the Y direction, and be spaced apart from each other in the X direction. That is, the first interconnect portion WP1 and the second interconnect portion WP2 included in the shield line SHL may be arranged in the shield line regions SHAa, SHAb, and SHAc in such a manner that the shield line SHL shown in FIG. 37 is rotated by 90 degrees.

### 3.2 Advantageous Effect of Present Embodiment

The third embodiment produces the advantageous effects similar to those of the first embodiment.

Furthermore, with the NAND flash memory 30 according to the present embodiment, the voltage VSS is applied by the shield line driver 45 to the first interconnect portion WP1 of the shield line SHL (the interconnect layer 112) provided in the plane region PLA, and the voltage VDDSA is applied by the shield line driver 45 to the second interconnect portion WP2 of the shield line SHL provided in the plane region PLA. This causes capacitance coupling between the second interconnect portion WP2 and an interconnect (for example, the bit line BL) facing thereto in the Z direction, thereby functioning as decoupling capacitors. This further causes capacitance coupling between the first interconnect portion WP1 and the second interconnect portion WP2 adjacent thereto in the X direction, thereby functioning as decoupling capacitors. That is, decoupling capacitors can be provided not only in the Z direction but also in the X direction. These decoupling capacitors function to supply an electric charge in response to varying of a power supply, thereby stabilizing the power supply VDDSA.

Furthermore, with the NAND flash memory 30 according to the present embodiment, the voltage VSS is supplied from the pad PD1 to the first interconnect portion WP1 of the shield line SHL (the interconnect layer 112) provided in the non-plane region, and the voltage VCC or VCCQ/VCCQL is supplied from the pad PD1 to the second interconnect portion WP2 of the shield line SHL provided in the non-plane region. This causes capacitance coupling between the second interconnect portion WP2 and an interconnect facing to the shield line SHL (for example, the interconnect layer 119) in the Z direction, thereby functioning as decoupling capacitors. This further causes capacitance coupling between the first interconnect portion WP1 and the second interconnect portion WP2 adjacent thereto in the X direction, thereby functioning as decoupling capacitors. That is, decoupling capacitors can be provided not only in the Z direction but also in the X direction. Accordingly, an electric charge can be supplied at a time when a power supply varies, thereby stabilizing the power supply voltage VCC or VCCQ/VCCQL.

Furthermore, in the NAND flash memory 30 according to the present embodiment, the layout of the shield line SHL is the same between the plane region PLA (the shield line regions SHAa and SHAb) and the non-plane region (shield line region SHAc). This can simplify the manufacturing process.

### 4. Modification, Etc.

As described above, a semiconductor memory according to an embodiment includes a first chip (200) including a first bonding surface and a substrate (201), the first bonding surface intersecting a first direction (Z), and a second chip (100) including a second bonding surface (P1), the second bonding surface intersecting the first direction and bonded to the first bonding surface of the first chip (200). The second chip (100) includes a first region (PLA) including a memory cell array (36) and a first shield line (SHL), and a second region (PDA, EDA) including a second shield line (SHL). The first shield line (SHL) is provided between the second bonding surface (P1) and the memory cell array (36). The second shield line (SHL) is provided in a same layer as the first shield line (SHL), and is not electrically coupled to the first shield line (SHL).

The embodiments are not limited to those described in the above, and various modifications can be made.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory comprising:
a first chip including a first bonding surface and a substrate, the first bonding surface intersecting a first direction; and
a second chip including a second bonding surface, the second bonding surface intersecting the first direction and bonded to the first bonding surface of the first chip,
wherein the second chip has a first region including a memory cell array and a first shield line, and a second region including a second shield line,
the first shield line is provided between the second bonding surface and the memory cell array, and
the second shield line is provided in a same layer as the first shield line and is not electrically coupled to the first shield line.

2. The memory according to claim 1, wherein
the memory cell array includes a bit line, and
the first shield line faces the bit line in the first direction.

3. The memory according to claim 2, wherein
the first chip includes a sense amplifier coupled to the bit line, and
the first shield line does not overlap the sense amplifier when viewed in the first direction.

4. The memory according to claim 1, wherein
the first chip includes a driver coupled to the first shield line and configured to apply a voltage to the first shield line.

5. The memory according to claim 4, wherein
the second region of the second chip further includes a pad which is externally exposed and configured to receive a power supply voltage, and
the second shield line is electrically coupled to the pad.

6. The memory according to claim 5, wherein
the driver supplies a first voltage to the second shield line, the first voltage being higher than a ground voltage and equal to or lower than the power supply voltage.

7. The memory according to claim 1, wherein
the first region extends in a second direction and a third direction when viewed in the first direction, the first to third directions intersecting one another,
the second region surrounds the first region when viewed in the first direction, and
the second shield line is provided on at least one side of the first region in the second direction.

8. The memory according to claim 1, wherein
the first direction intersects the first plane,
each of the first shield line and the second shield line includes a plurality of interconnect portions, and
the interconnect portions are each formed into a line shape extending in a second direction, and being apart from each other in a third direction, the first to third directions intersecting one another.

9. The memory according to claim 1, wherein
the first region extends in a second direction and a third direction when viewed in the first direction, the first to third directions intersecting one another,
the second region surrounds the first region when viewed in the first direction, and
the second shield line is provided on
both sides of the first region in the second direction, and
at least one side of the first region in the third direction.

10. The memory according to claim 1, wherein
the memory cell array includes a plurality of memory cells and a plurality of bit lines, the bit lines being respectively coupled to one ends of the memory cells,
the first shield line faces the bit lines in the first direction,
the first chip includes a driver coupled to the first shield line and configured to apply a voltage to the first shield line,
a write operation is performed to the memory cells such that one of the memory cells is a write target and another one of the memory cells is a non-write target, the write operation including i times of program loops, each program loop including a program operation and a program verify operation, i being an integer greater than 1,
in the program operation of at least one of first to j-th times of the program loops, j being an integer equal to or greater than 1 and smaller than i, the driver applies a second voltage to the first shield line, the second voltage being the same with a voltage to be applied to one of the bit lines coupled to the one of the memory cells as the write target, and
in the program operation of at least one of (j+1)-th time to an i-th time times of the program loops, the driver applies a third voltage to the first shield line, the third voltage being the same with a voltage to be applied to another one of the bit lines coupled to the another one of the memory cells as the non-write target.

11. The memory according to claim 1, wherein
the memory cell array includes a plurality of memory cells and a plurality of bit lines, the bit lines being respectively coupled to one ends of the memory cells,
the first shield line faces the bit lines in the first direction,
the first chip includes a driver coupled to the first shield line and configured to apply a voltage to the first shield line,
a write operation is performed to the memory cells such that one of the memory cells is a write target and another one of the memory cells is a non-write target, the write operation including i times of program loops, each program loop including a program operation and a program verify operation, i being an integer greater than 2,
in the program operation of a first time of the program loops, the driver applies a fourth voltage to the first shield line, the fourth voltage being the same with a voltage to be applied to one of the bit lines coupled to the one of the memory cells as the write target,
in the program operation of a k-th time of the program loops, k being an integer greater than 1 and smaller than i, the driver applies a fifth voltage higher than the fourth voltage to the first shield line, and
in the program operation of an i-th time of the program loops, the driver applies a sixth voltage higher than the fifth voltage to the first shield line.

12. The memory according to claim 1, wherein
the first shield line includes a plurality of interconnect portions each formed into a line shape extending in a second direction, and being apart from each other in a third direction, the first to third directions intersecting one another,
the memory cell array includes a plurality of memory cells and a plurality of bit lines, the bit lines being respectively coupled to one ends of the memory cells,
the interconnect portions respectively face the bit lines in the first direction,
the first chip includes a driver coupled to the interconnect portions and configured to apply a voltage to the interconnect portions,
a write operation is performed to the memory cells such that one of the memory cells is a write target and another one of the memory cells is a non-write target, the write operation including a plurality of program loops, each program loop including a program operation and a program verify operation, and
in the program operation of at least one of the program loops, the driver applied a seventh voltage to one of the interconnect portions of the first shield line which faces one of the bit lines coupled to the one of the memory cells as the write target and apply an eighth voltage different from the seventh voltage to another one of the interconnect portions which faces another one of the bit lines coupled to the another one of the memory cells as the non-write target.

13. The memory according to claim 1, wherein
the memory cell array includes a plurality of memory cells, a plurality of bit lines, and a source line, the bit lines being respectively coupled to one ends of the memory cells, the source line being commonly coupled to the other ends of the memory cells,
the first shield line faces the bit lines in the first direction,
the first chip includes a sense amplifier coupled to the bit lines, and a driver coupled to the first shield line and configured to apply a voltage to the first shield line, and
in a read operation, the driver applies a ninth voltage to the first shield line, the ninth voltage being the same with a voltage to be applied to the source line.

14. The memory according to claim 1, wherein
the memory cell array includes a plurality of memory cells, a plurality of bit lines, a word line, and a source line, the bit lines being respectively coupled to one ends of the memory cells, the word line being commonly coupled to gates of the memory cells, the source line being commonly coupled to the other ends of the memory cells,
the first shield line faces the bit lines in the first direction,
the first chip includes a sense amplifier coupled to the bit lines, and a driver coupled to the first shield line and configured to apply a voltage to the first shield line,
in a first read operation performed to the memory cells while applying a tenth voltage to the word line, the driver applies an eleventh voltage to the first shield line, and
in a second read operation performed to the memory cells while applying a twelfth voltage different from the tenth voltage to the word line, the driver applies a thirteenth voltage different from the eleventh voltage to the first shield line.

15. The memory according to claim 14, wherein
each of the eleventh voltage and the thirteenth voltage is ranging between a voltage to be applied to the source line and a voltage to be applied to the bit lines.

16. The memory according to claim 14, wherein
the twelfth voltage is greater than the tenth voltage, and
the thirteens voltage is smaller than the eleventh voltage.

17. The memory according to claim 1, wherein
the memory cell array includes a plurality of memory cells, a plurality of bit lines, and a word line, the bit lines being respectively coupled to one ends of the memory cells, the word line being commonly coupled to gates of the memory cells,
the first shield line faces the bit lines in the first direction,
the first chip includes a driver coupled to the first shield line and configured to apply a voltage to the first shield line,
an erase operation is performed to the memory cells, the erase operation including a plurality of erase loops, each erase loop including an erase voltage application operation and an erase verify operation, and
in the erase voltage application operation while applying a fifteenth voltage to the bit lines and applying a sixteenth voltage lower than the fifteenth voltage to the word line, the driver applies a seventeenth voltage greater than the sixteenth voltage to the first shield line.

18. The memory according to claim 1, wherein
the first shield line includes a first interconnect portion and a second interconnect portion,
each of the first interconnect portion and the second interconnect portion includes a base portion, a hookup portion, and a plurality of projecting portions,
the base portion is formed into a line shape extending in a second direction intersecting the first direction,
the hookup portion is coupled to a part of the base portion and is formed into a line shape extending in a third direction intersecting the first direction and the second direction,
the projecting portions are coupled to a part of the hookup portion, are each formed into a line shape extending in the second direction, and are apart from each other in the third direction,
the hookup portion of the first interconnect portion is apart from the base portion of the second interconnect portion in the third direction,
the hookup portion of the second interconnect portion is apart from the base portion of the first interconnect portion in the third direction,
the projecting portions of the first interconnect portion are apart from the hookup portion of the second interconnect portion in the second direction,
the projecting portions of the second interconnect portion are apart from the hookup portion of the first interconnect portion in the second direction,
each of the projecting portions of the first interconnect portion and each of the projecting portions of the second interconnect portion are alternatively arranged and are apart from each other in the third direction,
the projecting portion coupled to an end portion in the third direction of the hookup portion of the first interconnect portion is apart from the base portion of the second interconnect portion, and
the projecting portion coupled to an end portion in the third direction of the hookup portion of the second interconnect portion is apart from the base portion of the first interconnect portion.

19. The memory according to claim 1, wherein
the memory cell array includes a plurality of memory cell transistors.

20. The memory according to claim 1, wherein
the semiconductor memory is a NAND flash memory.
